(19) United States
(12) Patent Application Publication
(10) Pub. No.: US 2023/0389357 A1
(43) Pub. Date: Nov. 30, 2023

(54) THIN FILM TRANSISTOR SUBSTRATE, METHOD FOR MANUFACTURING THEREOF, AND DISPLAY APPARATUS COMPRISING THE THIN FILM TRANSISTOR SUBSTRATE

(71) Applicant: LG DISPLAY CO., LTD., Seoul (KR)

(72) Inventor: JaeHyun KIM, Gyeonggi-do (KR)

(73) Assignee: LG DISPLAY CO., LTD., SEOUL (KR)

(21) Appl. No.: 18/201,509

(22) Filed: May 24, 2023

(30) Foreign Application Priority Data
May 25, 2022 (KR) 10-2022-0064215

(51) Int. Cl. H10K 59/121; H10K 59/12

(52) U.S. Cl. CPC H10K 59/1213; H10K 59/1201

(57) ABSTRACT

A thin film transistor substrate includes a first thin film transistor and a second thin film transistor on the base substrate, the first active layer of the first thin film transistor includes a first channel part overlapping with a first gate electrode and a first conductive part penetration region, the second active layer of the second thin film transistor includes the second channel part overlapping with a second gate electrode, a second conductive part penetration region, and a length of the first conductive part penetration region is longer than the second conductive part penetration region.

### CROSS-REFERENCE TO RELATED APPLICATION

This application claims the priority of Korean Patent Application No. 10-2022-0064215 filed on May 25, 2022, which is hereby incorporated by reference in its entirety.

### BACKGROUND

### Field of the Disclosure

The present disclosure relates to a thin film transistor substrate, a manufacturing method thereof, and a display apparatus comprising the thin film transistor substrate.

### Description of the Background

The thin film transistor may be generally divided into an amorphous silicon thin film transistor using amorphous silicon as an active layer, a polycrystalline silicon thin film transistor using polycrystalline silicon as an active layer, an oxide semiconductor thin film transistor using an oxide semiconductor as an active layer, and other semiconductor thin film transistor using another semiconductor, such as compound semiconductor, etc., as an active layer.

Oxide semiconductor thin film transistors, which have a relatively large resistance change depending on the oxygen content, have the advantage of being able to easily obtain desired physical properties. In addition, in the manufacturing process of an oxide semiconductor thin film transistor, an oxide constituting an active layer may be formed at a relatively low temperature, so the manufacturing cost is low. Due to the characteristics of the oxide, since the oxide semiconductor could be transparent, it is also advantageous to implement a transparent display apparatus.

The description provided in the background section should not be assumed to be prior art merely because it is mentioned in or associated with the background section. The background section may include information that describes one or more aspects of the subject technology.

When a thin film transistor substrate is applied to a display device with a high pixel density, the gate length or channel length of the thin film transistor may be limited depending on the layout structure, thus it is difficult to secure an electrical characteristic margin.

For example, in the case of a thin film transistor substrate containing a plurality of conventional thin film transistors, since all of the thin film transistors have the same or similar active layer conductive part and conductive part penetration region, the electrical behavior of the threshold voltage change, according to a reduction of the length of the gate electrode, is similar. As a result, it is difficult to simultaneously implement thin film transistors with suppressed short channel effects such as hot carrier stress HCS, drain-induced barrier lowering DIBL, and threshold voltage roll-off phenomena, and other thin film transistors that require low threshold voltages, and thus it is difficult to secure process margins.

### SUMMARY

Accordingly, the present disclosure has been made in view of the above problems or limitations as described above, and more specifically, the present disclosure to provide a thin film transistor substrate which individually controls the threshold voltages of a thin film transistor with short channel length and another thin film transistor requiring low threshold voltage, and suppresses a short channel effect of a thin film transistor with a short channel length, and minimizes or reduces the threshold voltage difference between a thin film transistor with a short channel length and another thin film transistor requiring a low threshold voltage.

The present disclosure is also to provide a thin film transistor substrate having different conductive part penetration region lengths for a plurality of transistors provided on the same plane, a display apparatus including the same and a method of manufacturing thereof.

The present disclosure is yet to provide a thin film transistor substrate with different threshold voltage and electrical characteristics of short channel length such as hot carrier stress HCS, drain-induced barrier lowering DIBL, and threshold voltage roll-off for a plurality of transistors provided on the same plane, a display apparatus including the same and a method of manufacturing thereof.

In accordance with an aspect of the present disclosure, the above and other features may be accomplished by the provision of a thin film transistor substrate comprising a first thin film transistor on a base substrate and a second thin film transistor spaced apart from the first thin film transistor, wherein the first thin film transistor includes a first active layer and a first gate electrode overlapping with at least partially with the first active layer, the second thin film transistor includes a second active layer and a second gate electrode overlapping with at least partially with the second active layer, the first active layer includes a first channel part overlapping with the first gate electrode and a first conductive part penetration region disposed at one side and the other side of the first channel part, the second active layer includes a second channel part overlapping with the second gate electrode and a second conductive part penetration region disposed at one side and the other side of the second channel part, and a length of the first conductive penetration region is longer that a length of the second conductive penetration region.

In accordance with an aspect of the present disclosure, the above and other features may be accomplished by the provision of a display apparatus comprising the thin film transistor substrate described above.

In accordance with another aspect of the present disclosure, the above and other features s may be accomplished by the provision of a method of manufacturing a thin film transistor substrate comprising a step of forming a first active layer and a second active layer on a base substrate; a step of forming a gate insulating layer on the first active layer and the second active layer; a step of forming a first gate electrode to overlap with at least partially with the first active layer; a step of forming a second gate electrode to overlap with at least partially with the second active layer; a step of performing a first impurity implantation process on the first active layer, and a step of performing a second impurity implantation process on the second active layer, wherein the first active layer includes a first channel part overlapping with the first gate electrode and a first conductive part penetration region formed at one end and the other end of the first channel part, the second active layer includes a second channel part overlapping with the second gate electrode and a second conductive part penetration region formed at one end and the other end of the second channel part, and a length of the first conductive part penetration region is longer than a length of the second conductive part penetration region.

It is to be understood that both the foregoing general description and the following detailed description are exemplary and explanatory and are intended to provide further explanation of the inventive concepts as claimed.

### BRIEF DESCRIPTION OF THE DRAWINGS

The above and other features and advantages of the present disclosure will be more clearly understood from the following detailed description taken in conjunction with the accompanying drawings, in which:

FIG. 1 is a cross-sectional view of a thin film transistor substrate according to an exemplary aspect of the present specification.

FIG. 2A is a cross-sectional view of a first thin film transistor of a thin film transistor substrate according to an exemplary aspect of the present specification.

FIG. 2B illustrates ion implantation concentrations in a vertical direction of a first thin film transistor of a thin film transistor substrate according to an exemplary aspect of the present specification.

FIG. 3A is a cross-sectional view of a second thin film transistor of a thin film transistor substrate according to an exemplary aspect of the present specification.

FIGS. 3B and 3C illustrate impurity concentration in a vertical direction of a second thin film transistor of a thin film transistor substrate according to an exemplary aspect of the present specification.

FIG. 4 illustrates impurity concentrations of active layers of a first thin film transistor and a second thin film transistor of a thin film transistor substrate according to an exemplary aspect of the present specification.

FIG. 5 illustrates a change curve of a threshold voltage according to a gate length of a first thin film transistor and a second thin film transistor of a thin film transistor substrate according to an exemplary aspect of the present specification.

FIG. 6 is a cross-sectional view of a thin film transistor substrate according to another exemplary aspect of the present specification.

FIGS. 7A to 7D illustrate a method of manufacturing a thin film transistor substrate according to an exemplary aspect of the present specification.

FIGS. 8A to 8D illustrate a method of manufacturing a thin film transistor substrate according to another exemplary aspect of the present specification.

FIG. 9 is a schematic diagram of a display apparatus according to another exemplary aspect of the present specification.

FIG. 10 is a circuit diagram of any one pixel of FIG. 9.

FIG. 11 is a plan view of the pixel of FIG. 10.

FIG. 12 is a cross-sectional view taken along line I-I′ of FIG. 10.

FIGS. 13 to 15 are circuit diagrams of any one pixel of a display apparatus according to another exemplary aspect of the present specification.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and features of the present disclosure, and implementation methods thereof will be clarified through the following aspects, described with reference to the accompanying drawings. The present disclosure may, however, be embodied in different forms and should not be construed as being limited to the aspects set forth herein. Rather, these aspects are provided so that this disclosure will be thorough and complete, and will fully convey the scope of the present disclosure to those skilled in the art. Further, the present disclosure is only defined by the scope of the claims.

In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The shapes, sizes, ratios, angles, and numbers disclosed in the drawings for describing aspects of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

Any implementation described herein as an “example” is not necessarily to be construed as preferred or advantageous over other implementations.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used. For example, where an element or layer is disposed “on” another element or layer, a third layer or element may be interposed therebetween.

The terms, such as “below,” “lower,” “above,” “upper” and the like, may be used herein to describe a relationship between element (s) as illustrated in the drawings. It will be understood that the terms are spatially relative and based on the orientation depicted in the drawings.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” “A,” “B,” “(a),” and “(b),” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other, and may be variously inter-operated with each other and driven technically The aspects of the present disclosure may be carried out independently from each other, or may be carried out together in a co-dependent relationship.

Unless otherwise defined, all terms (including technical and scientific terms) used herein have the same meaning as commonly understood by one of ordinary skill in the art to which example aspects belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the drawings, the same or similar elements are denoted by the same reference numerals even though they are depicted in different drawings.

In the aspects of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one aspect of the present disclosure may be the drain electrode in another exemplary aspect of the present disclosure, and the drain electrode in any one aspect of the present disclosure may be the source electrode in another exemplary aspect of the present disclosure.

In one or more aspects of the present disclosure, for convenience of explanation, a source region is distinguished from a source electrode, and a drain region is distinguished from a drain electrode. However, aspects of the present disclosure are not limited to this structure. For example, a source region may be a source electrode, and a drain region may be a drain electrode. Also, a source region may be a drain electrode, and a drain region may be a source electrode.

FIG. 1 is a cross-sectional view of a thin film transistor substrate according to an exemplary aspect of the present specification.

Referring to FIG. 1, a thin film transistor substrate 1 according to an exemplary aspect of the present specification includes a base substrate 110, a first thin film transistor TR1 on the base substrate 110, and a second thin film transistor TR2 on the base substrate 110. The number of the thin film transistors on the base substrate 110 are not limited thereto. As an example, more than two thin film transistors could be disposed on the base substrate 110. The thin film transistor substrate 1 according to an exemplary aspect of the present specification may include the base substrate 110, a buffer layer 120, light blocking layers 131 and 132, active layers A1 and A2, a gate insulating layer 140, gate electrodes G1 and G2, a first interlayer insulating layer 150, a second interlayer insulating layer 160, source electrodes S1 and S2 and drain electrodes D1 and D2.

The base substrate 110 may be a glass substrate, a thin glass substrate that may be bent or bent, a plastic substrate, or a silicon wafer substrate, but not limited thereto. As an example, the base substrate 110 may be a rigid substrate, and/or may be made of a metal materials or inorganic non-metallic materials. As the plastic, transparent plastic having flexible properties, for example, polyimide, polyethylene terephthalate (PET), polyethylene naphthalate (PEN), polycarbonate (PC), polyethersulfone (PES), polyarylate (PAR), polysulfone (PSF), or cyclic-olefin copolymer (COC) may be used. When polyimide is used as the base substrate 110, considering that a high-temperature deposition process is performed on the base substrate 110, a heat-resistant polyimide capable of enduring high temperatures may be used. In addition, the substrate 110 may be formed of a multilayer where an organic layer and an inorganic layer are alternately stacked. For example, the substrate 101 may be formed by alternately stacking an organic layer such as polyimide and an inorganic layer such as silicon oxide (SiOx).

The buffer layer 120 may be disposed on the base substrate 110 to prevent the penetration of water from the outside. The buffer layer 120 may be commonly disposed on the base substrate 110 of the first thin film transistor TR1 and the second thin film transistor TR2. The buffer layer 120 may be formed of a multilayer film where one or more inorganic films of a silicon oxide layer SiOx, a silicon nitride layer SixNy, and/or a silicon oxynitride layer SixOyNz are laminated. For example, the buffer layer 120 may include a first buffer layer 121 on the base substrate 110 and a second buffer layer 122 on the first buffer layer 121. But aspects are not limited thereto. As an example, the buffer layer 120 may be also formed of a single layer film of inorganic films, or even be omitted as necessary.

Light blocking layers 131 and 132 may be disposed on the base substrate 110.

The light blocking layers 131 and 132 may protect the active layers A1 and A2 and the first and second thin film transistors TR1 and TR2 by blocking light incident from the outside. The light blocking layers 131 and 132 may be made of a material having light blocking characteristics or light reflection characteristics. The light blocking layers 131 and 132 may include a lower light blocking layer and an upper light blocking layer, without being limited thereto. As an example, the light blocking layers 131 and 132 may include one single layer or more than two layers, or even be omitted as necessary. The light blocking layers 131 and 132 may not be disposed on the whole surface of the base substrate 110 but may be disposed only correspondingly to the thin film transistors TR1 and TR2 or on at least a portion overlapping with the first active layer A1 and the second active layer A2.

The first light blocking layer 131 may be formed to at least partially overlap with the first active layer A1 of the first thin film transistor TR1 or the first thin film transistor TR1, and the second light blocking layer 132 may be formed to at least partially overlap with the second thin film transistor TR2 or the second active layer A2 of the second thin film transistor TR2. For example, a width of the first light blocking layer 131 may be formed to greater than or same as that of the first active layer A1 of the first thin film transistor TR1 or the first thin film transistor TR1, and a width of the second light blocking layer 132 may be formed to greater than or same as that of the second thin film transistor TR2 or the second active layer A2 of the second thin film transistor TR2.

According to an exemplary aspect of the present specification, the buffer layer 120 may be disposed on the light blocking layers 131 and 132 and the base substrate 110. In FIG. 1, the light blocking layers 131, 132 are shown to be formed on the base substrate 110, but are not limited thereto, and may be formed on, for example, the first buffer layer 121, etc. As another example, the light blocking layers 131, 132 may be disposed in the buffer layer 120. For example, the light blocking layers 131, 132 may be disposed between e a first buffer layer 121 and a second buffer layer 122.

The first thin film transistor TR1 includes a first active layer A1 including an oxide semiconductor, a first gate electrode G1 formed to be spaced apart on the first active layer A1, a gate insulating layer 140 disposed between the first active layer A1 and the first gate electrode G1.

The second thin film transistor TR2 includes a second active layer A2 including an oxide semiconductor, a second gate electrode G2 formed to be spaced apart on the second active layer A2, and a gate insulating layer 140 disposed between the second active layer A2 and the second gate electrode G2.

The first active layer A1 of the first thin film transistor TR1 and the second active layer A2 of the second thin film transistor TR2 may be disposed on the buffer layer 120, etc.

The first active layer A1 of the first thin film transistor TR1 may be disposed to overlap with the first gate electrode G1, a first source electrode S1, and a first drain electrode D1. The first active layer A1 of the first thin film transistor TR1 includes a first channel part A11, first conductive parts A13a and A13b, and first conductive part penetration regions A12a and A12b between the first channel part A11 and the first conductive parts A13a and A13b.

The first channel part A11 may overlap with the first gate electrode G1 and may be defined as an area except for the first conductive part penetration regions A12a and A12b overlapping with the first gate electrode G1. The first channel part A11 may be set to have a first length L1.

The first conductive part penetration regions A12a and A12b may be defined as regions being located at one end and the other end of the first channel part A11 and partially overlapping with the first gate electrode G1. Here, one end and the other end of the first channel part A11 may mean both ends of the first channel part A11 in the first direction X or in the horizontal direction. The first conductive part penetration regions A12a and A12b may be located between the first channel part A11 and the first conductive parts A13a and A13b, respectively. The first conductive part penetration regions A12a and A12b may be set to have a second length L2, without being limited thereto. As an example, the first conductive part penetration regions A12a and A12b may be set to have different lengths.

The first conductive parts A13a and A13b are disposed on one side and the other side of the first channel part A11. Here, the one side and the other side of the first channel part A11 may refer to a portion of the first active layer A1 spaced apart from both ends of the first channel part A11 in the first direction X or the horizontal direction by a certain distance. For example, the first conductive parts A13a and A13b of the first thin film transistor TR1 may be defined as areas of first active layer A1 that does not overlap with the first gate electrode G1. The first conductive parts A13a and A13b may be set to have a third length L3, without being limited thereto. As an example, the first conductive parts A13a and A13b may be set to have different lengths.

The second active layer A2 of the second thin film transistor TR2 may be disposed to overlap with the second gate electrode G2, a second source electrode S2, and a second drain electrode D2. The second active layer A2 of the second thin film transistor TR2 includes a second channel part A21, second conductive parts A23a and A23b, and second conductive part penetration regions A22a and A22b between the second channel part A21 and the second conductive parts A23a and A23b.

The second channel part A21 may overlap with the second gate electrode G2 and may be defined as an area except for the second conductive part penetration regions A22a and A22b overlapping with the second gate electrode G2. The second channel part A21 may be set to have a fourth length L4. In accordance with an exemplary aspect of present specification, the first length L1 may be set to be equal to or longer than the fourth length L4, but the aspect of this specification is not limited thereto.

The second conductive part penetration regions A22a and A22b may be defined as region being located at one end and the other end of the second channel part A21 and partially overlapping with the second gate electrode G2. Here, one end and the other end of the second channel part A21 may mean both ends of the second channel part A21 in the first direction X or in the horizontal direction. The second conductive part penetration regions A22a and A22b may be positioned between the second channel part A21 and the second conductive parts A23a and A23b, respectively. The second conductive part penetration regions A22a and A22b may be set to have a fifth length L5, without being limited thereto. As an example, the second conductive part penetration regions A22a and A22b may be set to have different lengths. According to an exemplary aspect of the present specification, the second length L2 may be set to be longer than the fifth length L5.

The second conductive parts A23a and A23b are disposed on one side and the other side of the second channel part A21. Here, the one side and the other side of the second channel part A21 may refer to a portion of the second active layer A2 spaced apart from both ends of the second channel part A21 in the first direction X or the horizontal direction by a certain distance. For example, the second conductive parts A23a and A23b of the second thin film transistor TR2 may be defined as areas of second active layer A2 that does not overlap with the second gate electrode G2. The second conductive parts A23a and A23b may be set to have a sixth length L6, without being limited thereto. As an example, the second conductive parts A23a and A23b may be set to have different lengths. According to an exemplary aspect of the present specification, the third length L3 may have the same length as or may be set to have a different length from the sixth length L6, but the aspect of the present specification is not limited thereto.

The first active layer A1 of the first thin film transistor TR1 and the second active layer A2 of the second thin film transistor TR2 may include an oxide semiconductor material, for example, one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InZnSnO)-based oxide semiconductor material, an ITZO (InSnZnO)-based oxide semiconductor material, an IGTO (InGaSnO)-based oxide semiconductor material, an GO (GaO)-based oxide semiconductor material, an GZTO (GaZnSnO)-based oxide semiconductor material, and an GZO (GaZnO)-based oxide semiconductor material. However, an exemplary aspect of the present specification is not limited thereto, and the first active layer A1 and the second active layer A2 may be formed by other oxide semiconductor materials known in the art, and/or may be formed by different oxide semiconductor materials (e. g., polycrystalline silicon semiconductor material).

For example, the first active layer A1 of the first thin film transistor TR1 and the second active layer A2 of the second thin film transistor TR2 may be formed of a single layer or multiple layers. When the first active layer A1 or the second active layer A2 is composed of multiple layers, at least one layer of the first active layer A1 or the second active layer A2 may include a material having higher mobility than other layers to compose a main active channel.

In addition, the first active layer A1 of the first thin film transistor TR1 may further include the first conductive part penetration regions A12a and A12b between the first channel part A11 and the first conductive parts A13a and A13b, and the first conductive part penetration regions A12a and A12b may be disposed between one side of the channel part A11 and one first conductive part A13a, and between the other side of the channel part A11 and the other first conductive part A13b, respectively.

According to another exemplary aspect of the present specification, the first active layer A1 overlapping with the first gate electrode G1 may be defined as a channel part, and the first channel part A11 may be defined as an area including the first conductive part penetration regions A12a and A12b. That is, the first conductive part penetration regions A12a and A12b may be constituted as parts of the first channel part A11.

The second active layer A2 of the second thin film transistor TR2 may further include second conductive part penetration regions A22a and A22b between the second channel part A21 and the second conductive parts A23a and A23b, and the second conductive part penetration regions A22a and A22b may be disposed between one side of the second channel part A21 and the one second conductive part A23a and between the other side of the second channel part A21 and the other second conductive part A23b, respectively.

According to another exemplary aspect of the present specification, the second active layer A2 overlapping with the second gate electrode G2 may be defined as a channel part, and the second channel part A21 may be defined as a region including the second conductive part penetration regions A22a and A22b. That is, the second conductive part penetration regions A22a and A22b may be constituted as parts of the second channel part A21.

The first conductive part penetration regions A12a and A12b and the second conductive part penetration regions A22a and A22b of present specification may be referred to as intermediate parts or lightly doped drain LDD, but are not limited thereto. Herein, the term “lightly doped” refers to a semiconductor material that has a low concentration of dopant atoms relative to the intrinsic semiconductor material. This means that only a small number of charge carriers (electrons or holes) are introduced into the material, and the overall electrical conductivity is moderately increased compared to the pure, undoped material.

The first interlayer insulating layer 150 and the second interlayer insulating layer 160 may be commonly disposed on the first gate electrode G1 of the first thin film transistor TR1, the second gate electrode G2 of the second thin film transistor TR2 and the gate insulating layer 140 and the second interlayer insulating layer 160 may be formed on the first interlayer insulating layer 150. But aspects are not limited thereto. As an example, at least one of the first interlayer insulating layer 150 and the second interlayer insulating layer 160 could be omitted as necessary.

The first interlayer insulating layer 150 may include a silicon oxide layer SiOx and/or a silicon nitride layer SiNx, etc., and may perform a function of protecting a thin film transistor. In addition, the first interlayer insulating layer 150 may be comprised of a silicon nitride (SiNx) layer and a silicon oxide (SiO₂) layer which are stacked in the order thereof.

The second interlayer insulating layer 160 may include a silicon oxide layer SiOx or a silicon nitride layer SiNx, etc., and may perform a function of protecting a thin film transistor. In addition, the second interlayer insulating layer 160 may be comprised of a silicon nitride (SiNx) layer and a silicon oxide (SiO₂) layer which are stacked in the order thereof.

The first source electrode S1 and the first drain electrode D1 may be disposed on the second interlayer insulating layer 160.

The first source electrode S1 and the first drain electrode D1 may be disposed to at least partially overlap with the first conductive parts A13a and A13b of the first thin film transistor TR1, and the second source electrode S2 and the second drain electrode D2 may be disposed to at least partially overlap with the second conductive parts A23a and A23b of the second thin film transistors TR2. The first source electrode S1 and the second source electrode S2 may serve as a source electrode, and the first drain electrode D1 and the second drain electrode D2 may serve as a drain electrode. However, the aspect of the present specification is not limited thereto, and the first source electrode S1 and the second source electrode S2 may serve as drain electrodes, and the first drain electrode D1 and the second drain electrode D2 may serve as source electrodes. In addition, the first conductive parts A13a and A13b and the second conductive parts A23a and A23b may serve as source electrodes and drain electrodes, respectively, and the first and second source electrodes S1 and S2, and the first and second drain electrodes D1 and D2 may serve as connection electrodes between devices.

The first source electrode S1 and the first drain electrode D1 may be connected to the first active layer A1 through first and second contact holes CH1 and CH2, respectively. Specifically, the first source electrode S1 may contact with one of the first conductive parts A13a and A13b through the first contact hole CH1 provided in at least a portion of the gate insulating layer 140, the first interlayer insulating layer 150, and the second interlayer insulating layer 160, and the first drain electrode D1 spaced apart from the first source electrode S1, may contact the other of the first conductive parts A13a and A13b through the second contact hole CH2 provided in at least a portion of the gate insulating layer 140, the first interlayer insulating layer 150, and the second interlayer insulating layer 160. In addition, according to another exemplary aspect of the present specification, the first source electrode S1 may contact with at least a portion of the first light blocking layer 131 through a third contact hole CH3 provided in at least a portion of the buffer layer 120, the gate insulating layer 140, the first interlayer insulating layer 150, and the second interlayer insulating layer 160.

The second source electrode S2 and the second drain electrode D2 may be connected to the second active layer A2 through fourth and fifth contact holes CH4 and CH5, respectively. Specifically, the second source electrode S2 may contact with one of the second conductive parts A23a and A23b through the fourth contact hole provided in at least a portion of the gate insulating layer 140, the first interlayer insulating layer 150 and the second interlayer insulating layer 160, and the second drain electrode D2 spaced apart from the second source electrode S2, may contact with the other one of the second conductive parts A23a and A23b through the fifth contact hole CH5 provided in at least a portion of the gate insulating layer 140, the first interlayer insulating layer 150 and the second interlayer insulating layer 160.

According to an exemplary aspect of the present specification, the length of the first conductive part penetration regions A12a and A12b of the first thin film transistor TR1 may be longer than the length of the second conductive part penetration regions A22a and A22b of the second thin film transistor TR2.

According to an exemplary aspect of the present specification, the lengths of the first conductive part penetration regions A12a and A12b of the first thin film transistor TR1 and the lengths of the second conductive part penetration regions A22a and A22b may be somewhat proportional to an impurity concentration, a dopant concentration, or an ion implantation concentration. Each of the first conductive part penetration regions A12a and A12b of the first thin film transistor TR1 and the second conductive part penetration regions A22a and A22b of the second thin film transistor TR2 may be formed by diffusions of impurities by a predetermined heat treatment step after the conductorization process (e. g., hydrogenation process, ion implantation process, etc.). Here, the diffusion distance of impurities from the first conductive parts A13a and A13b and the second conductive parts A23a and A23b to the first conductive part penetration regions A12a and A12b and the second conductive part penetration regions A22a and A22b may be proportional to the impurity concentration and the heat treatment temperature. Assuming that the heat treatment temperature is the same or that the heat treatment is not accompanied, the diffusion distance of impurities may be proportional to the concentration of impurities. Here, impurities, dopants, or ions may refer to substantially the same thing, and impurities, dopants, or ions may refer to materials included in the active layer including an oxide semiconductor to improve electrical conductivity or channel mobility of the active layer. Herein, hydrogenation process refers to a process in which the hydrogen particles may penetrate into the first conductive parts A13a and A13b to fill voids in the first semiconductor pattern A1 with hydrogen, thereby improving and stabilizing the conductivity of the oxide or polycrystalline semiconductor material.

Here, the impurity, the dopant, or the ion may include at least one of boron B, phosphorus P, fluorine F, and hydrogen H, without being limited thereto.

For example, when the impurity concentration or ion implantation concentration of the first conductive parts A13a and A13b is higher than the impurity concentration or ion implantation concentration of the second conductive parts A23a and A23b, the length of the first conductive part penetration regions A12a and A12b of the first thin film transistor TR1 may be greater than that of the second conductive part penetration regions A22a and A22b of the second thin film transistor TR2.

In the thin film transistor according to an exemplary aspect of the present specification, the first thin film transistor TR1 may be a driving transistor, and the second thin film transistor TR2 may be a switching transistor, without being limited thereto. As an example, the first thin film transistor TR1 and the second thin film transistor TR2 may be other transistors, such as a reference transistor, a light emission control transistor, etc., in a display apparatus or even transistors in an apparatus other than a display apparatus.

According to an example of this specification, since the driving transistor may degrade PBTS stability characteristics as a threshold voltage increases, it may be advantage to implement the driving transistor to have a predetermined low threshold voltage, and it may be advantage to implement the switching transistor having a relatively shorter channel length and suppress a short channel effect due to a short channel length.

In addition, the second thin film transistor TR2 may be a thin film transistor constituting a gate driver, for example, a gate driver of a gate in panel GIP circuit, of a display apparatus.

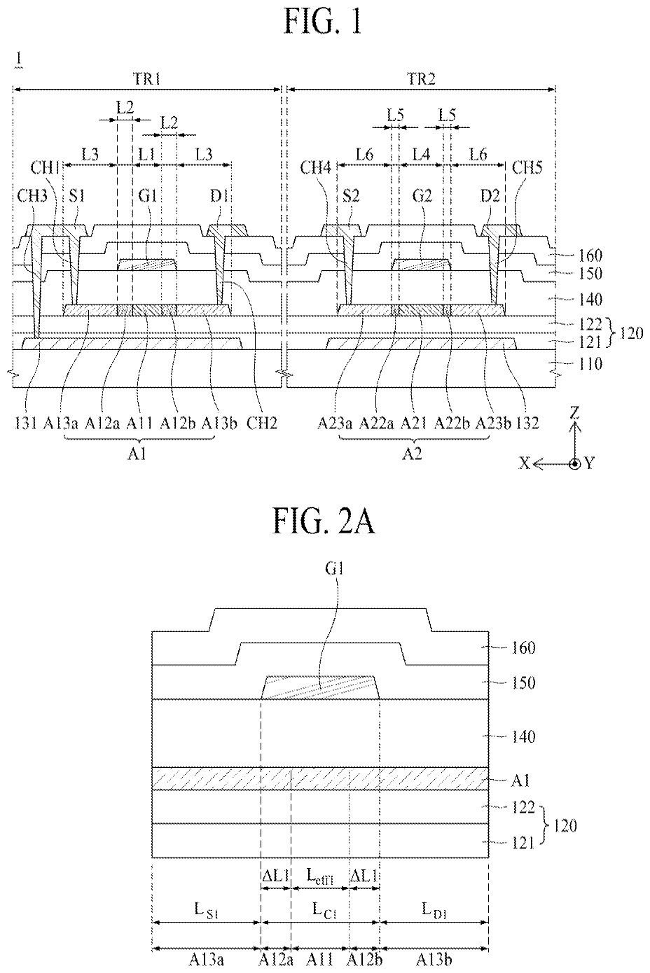

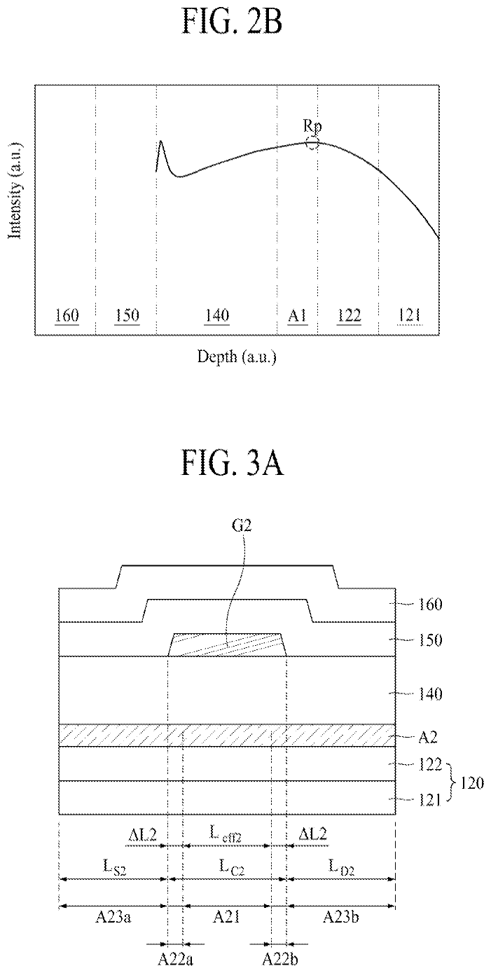

FIG. 2A is a cross-sectional view of a first thin film transistor of a thin film transistor substrate according to an exemplary aspect of the present specification, and FIG. 2B shows an ion implantation concentration in a vertical direction of the first thin film transistor of the thin film transistor substrate according to an exemplary aspect of the present specification.

Referring to FIG. 2A, the ideal length of the channel part of the first active layer A1 may be defined as the channel length when the first conductive part penetration regions A12a and A12b are not formed. Therefore, when the first conductive part penetration regions A12a and A12b are not formed, the ideal length of the channel part may be the same as a length L_{C1} of the first active layer A1 overlapping with the first gate electrode G1 of the first thin film transistor TR1.

Here, the length L_{C1} of the first active layer A1 overlapping with the first gate electrode G1 of the first thin film transistor TR1 may be defined as an area including the first channel part A11 and the first conductive part penetration regions A12a and A12b. In addition, the first conductive parts A13a and A13b may have a first source region length L_{S1} and a first drain region length LD₁.

A first effective channel length L_{eff1} of the first active layer A1 may be defined as a length L_{C2}−2*ΔL1 excluding a length of the first conductive part penetration regions ΔL1 of both sides of the first channel part A11 from the length L_{C1} of the first active layer A1 overlapping with the first gate electrode G1 of the first thin film transistor TR1. Therefore, when the length of the first conductive part penetration regions ΔL1 increases, the first effective channel length L_{eff1} of the first active layer A1 may be shortened, the threshold voltage may be reduced, and the threshold voltage may be further reduced by the threshold voltage roll-off phenomenon due to the short channel effect. The thin film transistor of FIG. 2A may be a driving transistor, without being limited thereto.

In FIG. 2B, a horizontal axis represents the depth of the second interlayer insulating layer 160, the first interlayer insulating layer 150, the gate insulating layer 140, the first active layer A1, the second buffer layer 122 and the first buffer layer 121, and a vertical axis represents an impurity concentration or an ion implantation concentration, and the vertical axis and the horizontal axis unit are arbitrary units. In addition, FIG. 2B illustrates the impurity concentration or the ion implantation concentration based on a virtual line in the third direction Z or the vertical direction of the region overlapping with the first conductive part A13a and A13b without overlapping with the first gate electrode G1 of the first thin film transistor TR1.

Referring to FIG. 2B, it may be seen that the impurity concentration or the ion implantation concentration is distributed from the gate insulating layer 140 to the buffer layers 122 and 121, and the impurity concentration or the ion implantation concentration shows the highest value in the region overlapping with the first active layer A1.

Here, the depth or region with the highest value of the impurity concentration or ion implantation concentration may be called projected range Rp. The impurity concentration or ion implantation concentration may have a Gaussian distribution approximately based on an Rp value, and a tail having a low concentration at a far side from the ion implantation surface may be formed. Here, the tail may be referred to as an impurity region in which impurities less penetrates in the Gaussian distribution. On the other hand, a region with a high impurity concentration or ion implantation concentration is formed near the surface of the gate insulation layer 140 or the ion implantation surface because of a collision between impurities or ions penetrating the surface of gate insulation layer 140 or the ion implantation surface and a lattice of the gate insulation layer 140. Therefore, the depth having such a high impurity concentration or ion implantation concentration is not considered as an Rp value.

In addition, since the impurity concentration or ion implantation concentration has a Gaussian distribution based on the Rp value as described above, the Rp value may be defined as the average depth of impurities performed by the impurity implantation process.

Here, the impurities may include at least one of boron B, phosphorus P, fluorine F, and hydrogen H, etc., and for example, FIG. 2B may illustrate a concentration distribution of boron B.

Accordingly, the first thin film transistor TR1 of the thin film transistor substrate 1 according to an exemplary aspect of the present specification may be formed such that the highest value or Rp of the impurity concentration or ion implantation concentration overlap withs with at least partially with the first active layer A1. In addition, the same impurities as the first active layer A1 in the first thin film transistor TR1 of the thin film transistor substrate 1 according to the exemplary aspect of the present specification may not be formed on the first interlayer insulating layer 150 and the second interlayer insulating layer 160.

In addition, the buffer layer 120 overlapping with the first thin film transistor TR1 may include the same or similar (e.g., less) impurities included in the first active layer A1.

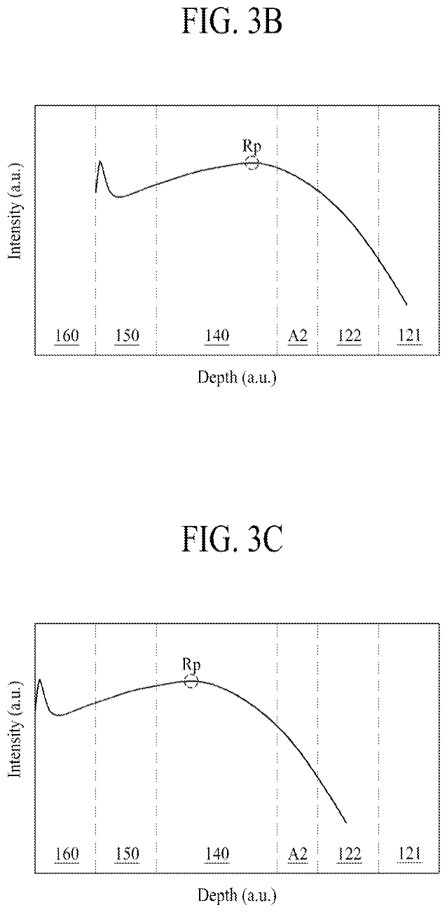

FIG. 3A is a cross-sectional view of a second thin film transistor of a thin film transistor substrate according to an exemplary aspect of the present specification, and FIGS. 3B and 3C show impurity concentrations in vertical direction of the second thin film transistor of the thin film transistor substrate according to an exemplary aspect of the present specification.

Referring to FIG. 3A, the ideal length of the channel part of the second active layer A2 may be defined as the channel length when the second conductive part penetration regions A22a and A22b are not formed. Therefore, when the second conductive part penetration regions A22a and A22b are not formed, the length of the ideal channel part may be the same as a length L_{C2} of the second active layer A2 overlapping with the second gate electrode G2 of the second thin film transistor TR2.

Here, the length L_{C2} of the second active layer A2 overlapping with the second gate electrode G2 of the second thin film transistor TR2 may be defined as an area including the second channel part A21 and the second conductive part penetration regions A22a and A22b. In addition, the second conductive parts A23a and A23b may have a second source region length L_{S2} and a second drain region length L_{D2}.

A Second effective channel length L_{eff2} of the second active layer A2 may be defined as a length L_{C2}−2*ΔL2 excluding a length of the second conductive part penetration regions ΔL2 of both sides of the second channel part A21 from the length LC2 of the second active layer A2 overlapping with the second gate electrode G2 of the second thin film transistor TR2.

Referring to FIGS. 2A and 3A, the length ΔL1 of the first conductive part penetration region may be set to be longer than the length ΔL2 of the second conductive part penetration region. Compared to the second thin film transistor TR2, the first effective channel length L_{eff1} of the first thin film transistor TR1 may be relatively further reduced, and accordingly, the threshold voltage may be reduced. Furthermore, the threshold voltage may be further reduced due to a threshold voltage roll-off phenomenon caused by a short channel effect. Compared to the first thin film transistor TR1, the second effective channel length L_{eff2} of the second thin film transistor TR2 may be relatively less reduced, thereby reducing the hot carrier stress HCS and threshold voltage roll-off effects, thereby securing a margin of electrical characteristics of the thin film transistor substrate. In addition, when the margin of electrical characteristics of the thin film transistor substrate of present specification increases, there is an advantage that the process margin may also be secured.

However, the length L_{C1} of the first active layer A1 overlapping with the first gate electrode G1, the length L_{S1} of the first source region and the length L_{D1} of the first drain region, and the length L_{C2} of the second active layer A2 overlapping with the second gate electrode G2, the length L_{S2} of the second source region and the length L_{D2} of the second drain region may change according to the manufacturing requirements or specifications of the first thin film transistor TR1 and the second thin film transistor TR2, accordingly, it may be formed to have the same length or different length.

The first thin film transistor TR1 may be a driving transistor, and the second thin film transistor may be a switching transistor, without being limited thereto.

In FIGS. 3B and 3C, the horizontal axis represents the depth of the second interlayer insulating layer 160, the first interlayer insulating layer 150, the gate insulating layer 140, the second active layer A2, the second buffer layer 122 and the first buffer layer 121, and the vertical axis and the horizontal axis unit are arbitrary units. FIGS. 3B and 3C illustrate the impurity concentration or the ion implantation concentration based on a virtual line in the third direction Z or vertical direction of the region overlapping with the second conductive parts A23a and A23b without overlapping with the second gate electrode G2 of the second thin film transistor TR2. In this case, the acceleration energy of the ion implantation process of FIGS. 3B and 3C is set in the same or similar manner as in FIG. 2B.

Referring to FIG. 3B, it may be seen that the impurity concentration or ion implantation concentration is distributed from the first interlayer insulating layer 150 to the buffer layers 122 and 121, and the impurity concentration or ion implantation concentration shows the highest value in the region overlapping with the gate insulating layer 140. Referring to FIG. 3C, it may be seen that the impurity concentration or ion implantation concentration is distributed from the second interlayer insulating layer 160 to the buffer layers 122 and 121, and the impurity concentration or ion implantation concentration shows the highest value in the region overlapping with the gate insulating layer 140.

Here, the depth or region with the highest value of the impurity concentration or ion implantation concentration may be called projected range Rp. The impurity concentration or ion implantation concentration may have a Gaussian distribution approximately based on the Rp value. On the other hand, a region with a high impurity concentration or ion implantation concentration is formed near the surface of the second interlayer insulating layer 160 (FIG. 3C) or the first interlayer insulating layer 150 (FIG. 3B) or ion implantation surface because of a collision between the impurities or ions penetrating the surface of the second interlayer insulating layer 160 (FIG. 3C) or the first interlayer insulating layer 150 (FIG. 3B) or ion implantation surface and a lattice of the second interlayer insulating layer 160 (FIG. 3C) or the first interlayer insulating layer 150 (FIG. 3B). Therefore, the depth having such a high impurity concentration or ion implantation concentration is not considered as an Rp value.

Therefore, the second thin film transistor TR2 of the thin film transistor substrate 1 according to the aspect of this specification may be formed such that the project range Rp, the depth which intersects the highest value of the impurity concentration or ion implantation concentration, does not overlap with at least partially with the second active layer A2, for example, the project range Rp overlap withs at least partially with the gate insulating layer 140.

In addition, the same or similar (e. g., less) impurity or ion implantation as the second active layer A2 in the second thin film transistor TR2 of the thin film transistor substrate 1 according to the aspect of the present specification may be formed in the first interlayer insulating layer 150 and/or the second interlayer insulating layer 160.

Referring to FIGS. 2B, 3B, and 3C, when the impurity implantation process is performed on the first thin film transistor TR1 and the second thin film transistor TR2 with the same or similar acceleration energy, in the first thin film transistor TR1 the impurity implantation process may be performed after forming the gate insulating layer 140, and in the second thin film transistor TR2 the impurity implantation process may be performed after forming the first interlayer insulation layer 150 or the second interlayer insulation layer 160. The Rp or the highest impurity concentration region may be formed differently in the first thin film transistor TR1 and the second thin film transistor TR2, for example, the first active layer A1 of the first thin film transistor TR1 may be formed relatively adjacent to Rp, and the second active layer A2 of the second thin film transistor TR2 may be formed relatively spaced apart from Rp. In this case, since the threshold voltage of the first thin film transistor TR1 shifts negatively and the threshold voltage of the second thin film transistor TR2 shifts positively, the threshold voltage difference between the second thin film transistor TR2 used as a switching transistor with a relatively short channel length or gate length and the first thin film transistor TR1 used as a driving transistor is reduced, thereby securing a margin of electrical characteristics of the thin film transistor substrate.

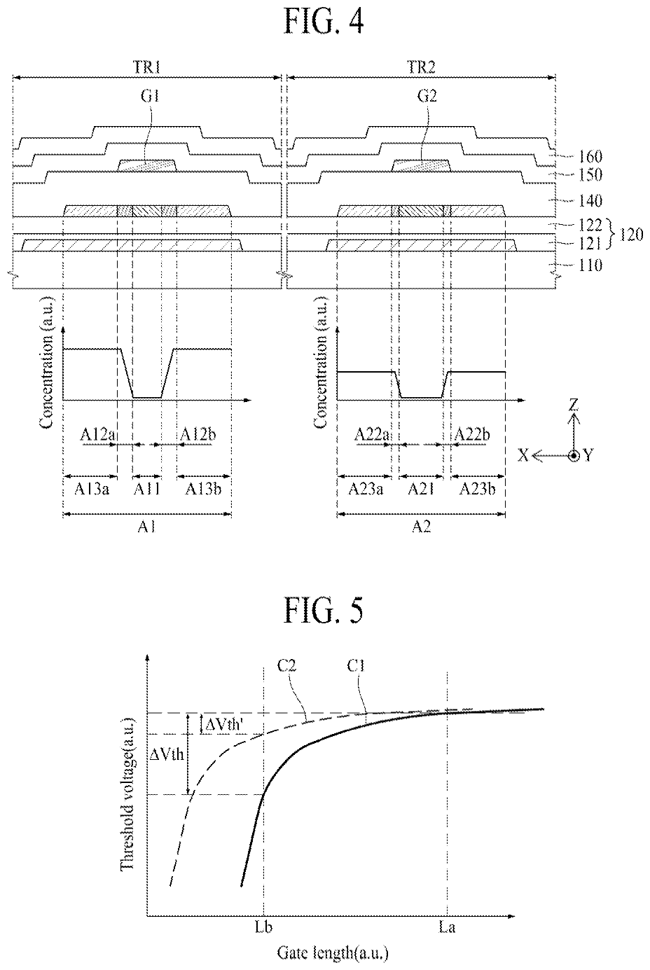

FIG. 4 illustrates impurity concentrations of active layers of a first thin film transistor and a second thin film transistor of a thin film transistor substrate according to an exemplary aspect of the present specification.

In FIG. 4, the concentration illustrates the impurity concentration or ion implantation concentration in the first direction X or the horizontal direction of the first active layer A1 and the second active layer A2, respectively. In FIG. 4, the horizontal axis represents the channel part, the conductive part, and the conductive part penetration region of the first active layer A1 and the second active layer A2, and the vertical axis represents the impurity concentration.

According to an exemplary aspect of the present specification, the dopant concentration of the first active layer A1 may be higher than the dopant concentration of the second active layer A2. Here, the dopant concentration of the first active layer A1 and the dopant concentration of the second active layer A2 may mean an average dopant concentration. Alternatively, the highest dopant concentration of the first active layer A1 may be higher than the highest dopant concentration of the second active layer A2.

Referring to FIG. 4, an impurity concentration or an ion implantation concentration of the first conductive parts A13a and A13b of the first active layer A1 may be higher than an impurity concentration or an ion implantation concentration of the second conductive parts A23a and A23b of the second active layer A2.

The first channel part A11 may be defined as an area having a non-doping state in which impurities are not injected while overlapping with the first gate electrode G1, and the second channel part A21 may be defined as an area having a non-doping state in which impurities are not injected while overlapping with the second gate electrode G2.

The first conductive parts A13a and A13b may be defined as a region disposed on one side and the other side of the first channel part A11 and having a doped concentration by an ion implantation process or an impurity implantation process while not overlapping with the first gate electrode G1.

Here, the one side and the other side of the first channel part A11 may refer to a portion of the first active layer A1 spaced apart from both ends of the first channel part A11 in the first direction X or the horizontal direction by a certain distance.

The second conductive parts A23a and A23b may be defined as a region disposed on one side and the other side of the second channel part A21 and having a doped concentration by an ion implantation process or an impurity implantation process while not overlapping with the second gate electrode G2.

Here, the one side and the other side of the second channel part A21 may refer to a portion of the second active layer A2 spaced apart from both ends of the second channel part A21 in the first direction X or the horizontal direction by a certain distance.

The first conductive part penetration regions A12a and A12b may be positioned, respectively, between the first channel part A11 and the first conductive parts A13a and A13b, may be defined as an area overlapping with at least partially with the first gate electrode G1, and may be defined as an area in which impurity concentration changes from one end to the other end of each of the first conductive part penetration regions A12a and A12b.

Here, the one end and the other end of the first conductive part penetration regions A12a and A12b may mean both ends of the first conductive part penetration regions A12a and A12b in the first direction X or in the horizontal direction. The one end and the other end of the first conductive part penetration regions A12a and A12b may have the same or similar impurity concentration as that of the first channel part A11 or the same or similar impurity concentration as that of the first conductive parts A13a and A13b, respectively.

The second conductive part penetration regions A22a and A22b may be positioned, respectively, between the second channel part A21 and the second conductive part A23a and A23b, may be defined as an area overlapping with at least partially with the second gate electrode G2, and may be defined as a region in which impurity concentration changes from one end to the other end of each of the second conductive part penetration regions A22a and A22b.

Here, the one end and the other end of the second conductive part penetration regions A22a and A22b may mean both ends of the second conductive part penetration regions A22a and A22b in the first direction X or in the horizontal direction. The one end and the other end of the second conductive part penetration regions A22a and A22b may have the same or similar impurity concentration as that of the second channel part A21 or the same or similar impurity concentration as that of the second conductive parts A23a and A23b, respectively.

Referring to FIGS. 4 and 2B, 3B, and 3C, by adjusting the ion implantation process, the first thin film transistor TR1 and the second thin film transistor TR2 may be prepared such that Rp is formed at different positions in the first thin film transistor TR1 and the second thin film transistor TR2, for example, the first thin film transistor TR1 may be formed such that the Rp of the ion implantation process overlaps with at least partially with the first active layer A1, and the second thin film transistor TR2 may be formed such that the Rp of the ion implantation process does not overlap with the second active layer A2, for example, the Rp of the ion implantation process may at least partially overlap with the gate insulating layer 140, first interlayer insulating layer 150 or the second interlayer insulating layer 160 overlapping with the second thin film transistor TR2. Accordingly, the concentration of the first conductive parts A13a and A13b of the first active layer A1 may be higher than the concentration of the second conductive parts A23a and A23b of the second active layer A2.

In addition, the impurity concentration or ion implantation concentration of the first conductive part penetration regions A12 and A12b of the first active layer A1 may be higher than the impurity concentration or ion implantation concentration of the second conductive part penetration regions A22a and A22b of the second active layer A2. Here, the concentration of each of the first conductive part penetration regions A12a and A12b of the first active layer A1 and the second conductive part penetration regions A22a and A22b of the second active layer A2 may mean the average concentration (as another example, the highest concentration) of each of the entire first conductive part penetration regions A12a and A12b of the first active layer A1 and the entire second conductive part penetration regions A22a and A22b of the second active layer A2.

The first channel part A11 of the first active layer A1 and the second channel part A21 of the second active layer A2 may have the same or similar impurity concentration or ion implantation concentration, for example, an undoped concentration in which impurities are not implanted.

Here, the same may mean a numerical value including a predetermined error range.

The concentration of the dopant may decrease or increase from one end to the other end in the first direction X of each of the first conductive part penetration regions A12a and A12b of the first thin film transistor TR1 and the second conductive part penetration regions A22a and A22b of the second thin film transistor TR2. Specifically, the first conductive part penetration regions A12a and A12b have a dopant concentration increasing in a direction from one end and the other end of the first channel part A11 toward the first conductive parts A13a and A13b, and the dopant concentration of the first conductive part penetration regions A12a and A12b of the first thin film transistor TR1 may decrease as it is closer to the first channel part A11, the second conductive part penetration regions A22a and A22b have a dopant concentration increasing in a direction from one end and the other end of the second channel part A21 toward the second conductive part A23a and A23b, and the dopant concentration of the second conductive part penetration regions A22a and A22b of the second thin film transistor TR2 may decrease as it is closer to the second channel part A21.

In addition, the impurity concentrations of the first conductive part penetration regions A12a and A12b may have the same or similar impurity concentration in a region in contact with the first channel part A11, and the impurity concentrations of the first conductive part penetration regions A12a and A12b may have the same or similar impurity concentration in a region in contact with the first conductive parts A13a and A13b. The impurity concentrations of the second conductive part penetration regions A22a and A22b may have the same or similar impurity concentration in a region in contact with the second channel part A21, and the impurity concentrations of the second conductive part penetration regions A22a and A22b may have the same or similar impurity concentration in a region in contact with the second conductive parts A23a and A23b. But aspects are not limited thereto. As an example, the impurity concentrations of the first conductive part penetration regions A12a and A12b may have the different impurity concentrations in a region in contact with the first channel part A11, and/or the impurity concentrations of the first conductive part penetration regions A12a and A12b may have different impurity concentrations in a region in contact with the first conductive parts A13a and A13b.

Although it is illustrated that the impurity concentration or ion implantation concentration of the first conductive part penetration regions A12a and A12b and the impurity concentration or ion implantation concentration of the second conductive part penetration regions A22a and A22b is changed linearly between the channel part and the conductive part, the impurity concentration or ion implantation concentration of the first conductive part penetration regions A12a and A12b and the impurity concentration or ion implantation concentration of the second conductive part penetration regions A22a and A22b may be changed linearly, exponentially, logistically, or stepwise between the channel part and the conductive part.

In addition, when the electrical characteristics of the second thin film transistor TR2 are secured, a separate impurity injection process may not be performed for the second thin film transistor TR2. In this case, the entire region of the second active layer A2 of the second thin film transistor TR2 may have the same impurity concentration.

FIG. 5 illustrates a change curve of a threshold voltage according to a gate length of a first thin film transistor and a second thin film transistor of a thin film transistor substrate according to an exemplary aspect of the present specification.

In FIG. 5, a horizontal axis represents a gate length of a gate electrode, a vertical axis represents a threshold voltage, and a unit of the vertical axis and the horizontal axis represents an arbitrary unit.

Referring to FIG. 5, the first thin film transistor TR1 and the second thin film transistor TR2 of the thin film transistor substrate 1 according to an exemplary aspect of the present specification may exhibit different electrical behavior with respect to a gate length or a gate electrode length. Here, the different electrical behavior may mean that the threshold voltage change rate according to the reduction of the gate length of the first thin film transistor TR1 and the second thin film transistor TR2 is different. The first thin film transistor TR1 and the second thin film transistor TR2 of the thin film transistor substrate 1 according to an exemplary aspect of the present specification may exhibit electrical characteristics such as different threshold voltages, on-current, carrier mobility, and short channel effects (Vth roll off, HCS, etc.). The first thin film transistor TR1 may be a driving transistor, and the second thin film transistor TR2 may be a switching transistor.

According to an exemplary aspect of the present specification, since the driving transistor may degrade positive bias temperature stress (PBTS) stability characteristics as the threshold voltage increases, it may be advantage to implement it to have a predetermined low threshold voltage, and the switching transistor may be implemented to suppress a short channel effect due to a short channel length.

In general, thin film transistors tend to decrease threshold voltage when gate length or gate electrode length decreases, and the tendency changes along a single curve with the same electrical behavior. Specifically, when adjusting the gate length or gate electrode length of different thin film transistors with the same electrical behavior, the change in threshold voltage may vary only along one curve, making it difficult to individually control the electrical characteristics of different thin film transistors or to secure the plurality of thin film transistors which have different electrical behaviors and tendencies, making it difficult to secure a margin for the electrical characteristics of the thin film transistor substrate.

However, according to the thin film transistor substrate 1 according to the aspect of this specification, the threshold voltage of the first thin film transistor TR1 may change according to the gate length or the gate electrode length along the first curve C1 of FIG. 5, and the threshold voltage of the second thin film transistor TR2 may change according to the second curve C2. For example, when the first thin film transistor TR1 composes a driving transistor requiring a low threshold voltage, the threshold voltage is changed along the first curve C1, and thus a low threshold voltage may be easily secured. And when the second thin film transistor TR2 composes a switching transistor in which a short channel effect shall be suppressed, the threshold voltage is changed along the second curve C2, and thus a short channel effect may be suppressed.

Specifically, the threshold voltage of the first thin film transistor TR1 may decrease by ΔVth while the gate length decreases from the first length La to the second length Lb, and the threshold voltage of the second thin film transistor TR2 may decrease by ΔVth′ while the gate length decreases from the first length La to the second length Lb, and ΔVth may be greater than ΔVth′.

Therefore, according to the thin film transistor substrate 1 according to the exemplary aspect of this specification, the first thin film transistor TR1 and the second thin film transistor TR2 may be formed to have different electrical behavior or threshold voltage changes with respect to the gate length.

In addition, according to the aspect of this specification, the second thin film transistor TR2 has the effect of reducing the short channel effect generated by the thin film transistor having a short channel length such as hot carrier stress (HCS) and a threshold voltage roll-off phenomenon compared to the first thin film transistor TR1, and the first thin film transistor TR1 may easily lower the threshold voltage, thereby preventing or reducing the PBTS (positive bias temperature stress) stability characteristics from deteriorating. Therefore, the thin film transistor substrate according to an exemplary aspect of the present specification has the advantage of securing a margin of electrical characteristics. In addition, when the margin of electrical characteristics of the thin film transistor substrate according to the aspect of this specification increases, the process margin for forming the thin film transistor substrate is also secured.

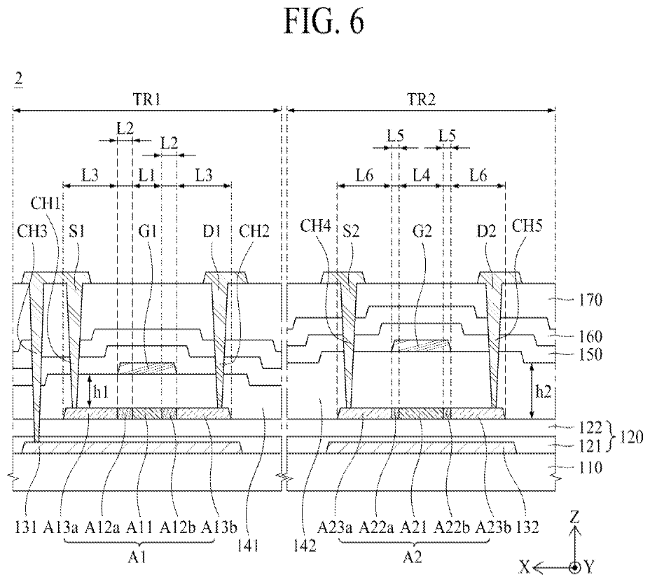

FIG. 6 is a cross-sectional view of a thin film transistor substrate according to another exemplary aspect of the present specification.

In FIG. 6, the thin film transistor substrate 2 according to another exemplary aspect of the present specification has the same structure except that the gate insulating layer 140 has a different structure compared to the thin film transistor substrate 1 according to an exemplary aspect of the present specification. Therefore, in FIG. 6, the same reference numerals are assigned to the same configuration as in FIG. 1, and the same or similar description will be omitted or briefly given.

Referring to FIG. 6, a first thin film transistor TR1 of a thin film transistor substrate 2 according to another exemplary aspect of this specification includes a first gate insulating layer 141 between the first gate electrode G1 and the first active layer A1, a second thin film transistor TR2 of the thin film transistor substrate 2 according to another exemplary aspect of this specification includes a second gate insulating layer 142 between the second gate electrode G2 and the second active layer A2, a first height h1 of the first gate insulating layer 141 may be different from (e. g., lower than) a second height h2 of the second gate insulating layer 142.

According to another exemplary aspect of the present specification, the first gate insulating layer 141 and the second gate insulating layer 142 may be formed by forming the same gate insulating layer and then etching only a region overlapping with the first thin film transistor TR1.

According to another exemplary aspect of the present specification, the first interlayer insulating layer 150 or the second interlayer insulating layer 160 overlapping with the first thin film transistor TR1 or the second thin film transistor TR2 may not contain the same impurity included in the first active layer A1 or the second active layer A2, the first and the second gate insulating layer 141 and 142 overlapping with the first thin film transistor TR1 or the second thin film transistor TR2 may contain the same impurity included in the first active layer A1 and the second active layer A2.

In addition, the buffer layer 120 overlapping with the first thin film transistor TR1 or the second thin film transistor TR2 may contain the same impurity included in the first active layer A1 and the second active layer A2.

In addition, the thin film transistor substrate 2 according to another exemplary aspect of the present specification may further include a third interlayer insulating layer 170 on the second interlayer insulating layer 160 and the third interlayer insulating layer 170 may perform a planarizing function if there is a difference between the first height h1 of the first gate insulating layer 141 of the first thin film transistor TR1 and the second height h2 of the second insulating layer 142. The third interlayer insulating layer 170 may include the same material or different material as the first interlayer insulating layer and the second interlayer insulating layers 150 and 160.

The third interlayer insulating layer 170 may be set to have a thickness of 100 nm to 400 nm, but the aspect of the present specification is not limited thereto.

The impurities such as impurities implanted into the first active layer A1 of the first thin film transistor TR1 and the second active layer A2 of the second thin film transistor TR2 of the thin film transistor substrate 2 according to another exemplary aspect of this specification may not be formed in the first interlayer insulating layer 150 and the second interlayer insulating layer 160.

According to an exemplary aspect of the present specification, the ion implantation process may be commonly performed on upper surfaces of the first gate insulating layer 141 having the first height h1 and the second gate insulating layer 142 having the second height h2, and Rp described in FIG. 2B may be formed to overlap with at least a portion of each of the first active layer A1 and the second active layer A2. However, for example, since the first active layer A1 may be injected with higher average impurity concentration than the second active layer A2, and more impurities may be injected into the first active layer A1 of the first thin film transistor TR1 having a higher threshold voltage value, the threshold voltage of the first thin film transistor TR1 may be relatively moved negatively. Accordingly, the threshold voltage deviation between the first thin film transistor TR1 and the second thin film transistor TR2 may be reduced.

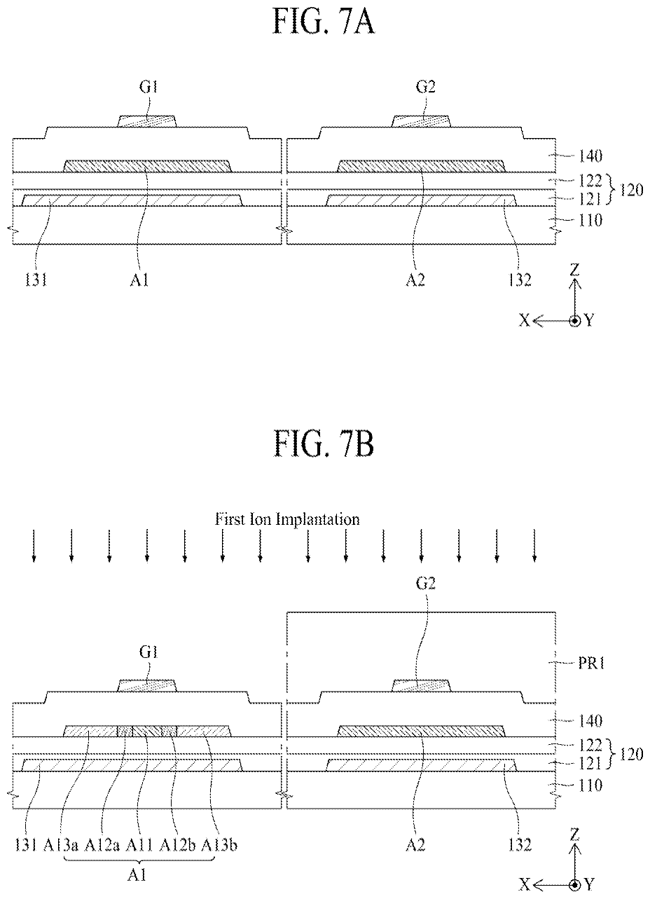

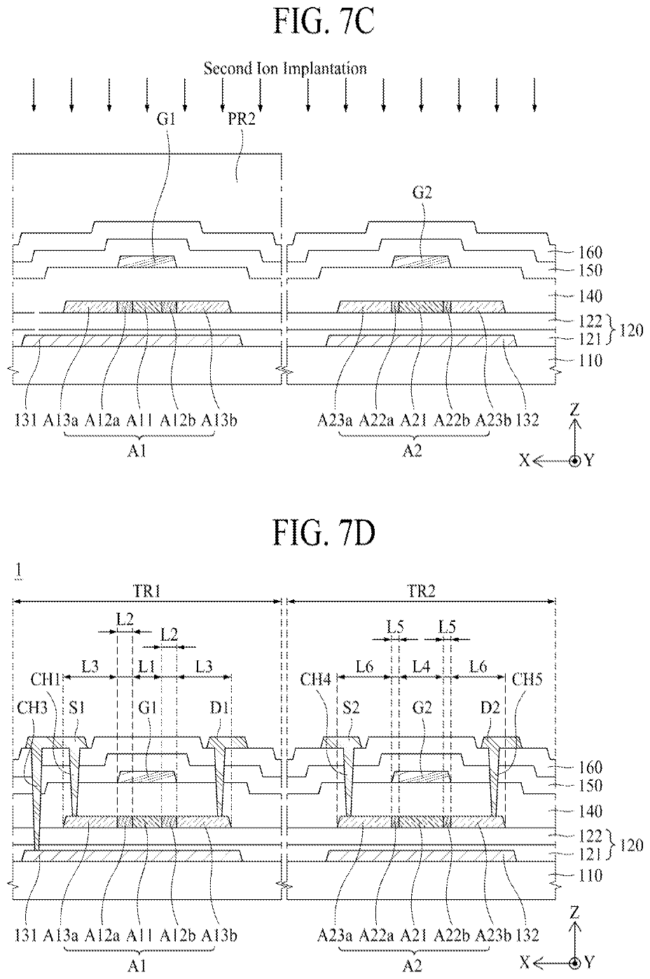

FIGS. 7A to 7D illustrate a method of manufacturing a thin film transistor substrate according to an exemplary aspect of the present specification.

A method of manufacturing the thin film transistor substrate according to an exemplary aspect of present specification, includes a step of forming an active layer material on a base substrate 110 and patterning the first active layer A1 and the second active layer A2, a step of forming a gate insulating layer 140 on the first active layer A1 and the second active layer A2, a step of forming a first gate electrode G1 overlapping with at least a portion of the first active layer A1, a step of forming a second gate electrode G2 overlapping with at least a portion of the second active layer A2, a step of forming a first photoresist pattern PR1 on a gate insulating layer 140, overlapping with the second active layer A2, and performing a first impurity implantation process, a step forming a first interlayer insulating layer 150 and/or a second interlayer insulating layer 160 on the first gate electrode G1 and the second gate electrode G2, and a step forming a second photoresist pattern PR2 overlapping with the first active layer A1 and performing a second impurity implantation process, the second photoresist pattern PR2 is formed on the first interlayer insulating layer 150 and the second interlayer insulating layer 160, the first active layer A1 includes a first channel part A11 overlapping with the first gate electrode G1, the channel part A11 includes first conductive part penetration regions A12a and A12b disposed on one end and the other end of the first channel part A11, the second active layer A2 includes a second channel part A21 overlapping with the second gate electrode G2, the second channel part A21 includes second conductive part penetration regions A22a and A22b disposed on one end and the other end of the second channel part A21, and a length of the first conductive part penetration regions A12a and A12b is longer than a length of the second conductive part penetration regions A22a and A22b.

The method of manufacturing a thin film transistor substrate according to an exemplary aspect of the present specification of FIGS. 7A to 7D describes a method of manufacturing the thin film transistor substrate according to an exemplary aspect of the present specification of FIG. 1. Accordingly, the same reference numerals as those of the thin film transistor substrate 1 of FIG. 1 are used, and the same or similar description will be omitted or briefly given.

Referring to FIG. 7A, a first light blocking layer 131 and a second light blocking layer 132 may be patterned in corresponding regions of the first thin film transistor TR1 and the second thin film transistor TR2, respectively, and a buffer layer 120 including first and second buffer layers 121 and 122 is formed on a base substrate 110. Next, a first active layer A1 and a second active layer A2 are patterned on the buffer layer 120 in corresponding regions of the first thin film transistor TR1 and the second thin film transistor TR2, respectively, and a gate insulating layer 140 is formed on the buffer layer 120 and the active layers A1 and A2. Next, the first gate electrode G1 is formed to overlap with at least partially with the first active layer A1, and a second gate electrode G2 is formed to overlap with at least partially with the second active layer A2.

For example, the gate insulating layer 140 may be set to have a thickness of 100 to 300 nm, but the aspect of the present specification is not limited thereto.

Referring to FIG. 7B, the first photoresist pattern PR1 is formed to overlap with a corresponding region of the second thin film transistor TR2, and a first ion implantation process is performed. The first ion implantation process may be performed on the first gate electrode G1 of the first thin film transistor TR1 and the gate insulating layer 140. In addition, the method may optionally include a heat treatment process for ion or impurity diffusion after performing the first ion implantation process.

For example, the impurity concentration of the first ion implantation process may range from 1e14 ions/cm 3 to 1e16 ions/cm 3, and the acceleration energy of the first ion implantation process may range from 20 keV to 100 keV, but the aspects of this specification are not limited thereto. Here, the impurity concentration and acceleration energy may be target values set in the ion implantation process apparatus.

Referring to FIG. 7C, after removing the first photoresist pattern PR1, the first interlayer insulating layer 150 and the second interlayer insulating layer 160 are sequentially formed on the gate electrodes G1 and G2 of the first thin film transistor TR1 and the second thin film transistor TR2. Next, the second photoresist pattern PR2 is formed to overlap with the corresponding region of the first thin film transistor TR1, and a second ion implantation process is performed. The second ion implantation process may be performed on the first interlayer insulating layer 150 and the second interlayer insulating layer 160 overlapping with the second thin film transistor TR2. In addition, the method may optionally include a heat treatment process for ion or impurity diffusion after performing the second ion implantation process.

For example, each of the first interlayer insulating layer 150 and the second interlayer insulating layer 160 may be set to have a thickness of 50 nm to 150 nm or 200 nm, but an exemplary aspect of the present specification is not limited thereto.

For example, the impurity concentration of the second ion implantation process may range from 1e14 ions/cm 3 to 1e16 ions/cm 3, and the acceleration energy of the second ion implantation process may range from 20 keV to 100 keV, but the aspects of this specification are not limited thereto. Here, the impurity concentration and acceleration energy may be target values set in the ion implantation process apparatus.

For example, the dopant used in the second ion implantation process may be the same as or different from the dopant used in the first ion implantation process.

Furthermore, although FIG. 7C illustrates that the second ion implantation process is performed after forming the second interlayer insulating layer 160, it may be performed after forming the first interlayer insulating layer 150, or when a third interlayer insulating layer 170 is contained, the second implantation process is performed after forming the third interlayer insulating layer 170. However, when the thickness of the third interlayer insulating layer 170 is set to exceed 200 nm, impurities by the second ion implantation process are difficult to be injected into the second active layer A2, and thus the second ion implantation process may be performed after the first interlayer insulating layer 150 or the second interlayer insulating layer 160 is formed.

In an example, the second ion implantation process described in FIG. 7C may be omitted in the method of manufacturing the thin film transistor substrate according to the aspect of present specification, and in this case, the active layer A2 of the second thin film transistor TR2 may be in a state in which impurities are not implanted. Meanwhile, when the active layer A2 of the second thin film transistor TR2 is not implanted with impurities, the threshold voltage of the second thin film transistor TR2 may be moved positive, so it is advantage to improve the conductivity of the corresponding regions of the second conductive parts A23a and A23b and the second conductive part penetration regions A22a and A22b of the second active layer A2. To this end, in another exemplary aspect of this disclosure, since the first interlayer insulating layer 150 and the second interlayer insulating layer 160 include hydrogen-containing silicon nitride SiNx:H, hydrogen may be supplied to the second active layer A2 by the silicon nitride SiNx:H. In this case, at least a portion of the second conductive parts A23a and A23b and the second conductive part penetration regions A22a and A22b may be conductorized to increase conductivity. When the hydrogen-containing silicon nitride SiNx:H is used as the first and second interlayer insulating layers 150 and 160, a conductorization of the active layer of the first thin film transistor TR1 and the second thin film transistor TR2 may be performed simultaneously. Therefore, the threshold voltages of the first thin film transistor TR1 and the second thin film transistor TR2 may be simultaneously lowered or moved negatively. In this case, if necessary, acceleration energy, impurity concentration, and the like of the first ion implantation process may be adjusted.

Referring to FIGS. 7B and 7C, an energy of the first ion implantation process may be greater than or less than an energy of the second ion implantation process. Here, the energy may mean acceleration energy and ion implantation energy of the ion implantation process. The first ion implantation process may be performed on the gate insulating layer 140, and the second ion implantation process may be performed on the first interlayer insulating layer 150 or the second interlayer insulating layer 160.

For example, the first ion implantation process may be performed with first acceleration energy so that Rp is formed in at least a portion of the first active layer A1, and the second ion implantation process may be performed with second acceleration energy so that Rp is not formed in at least a portion of the second active layer A2. In this case, the distance from the surface where the second ion implantation is performed to the second active layer A2 may be longer than the distance from the surface where the first ion implantation is performed to the first active layer A1. The first acceleration energy may be set to a value greater than the second acceleration energy to position Rp or the highest impurity concentration region in the first active layer A1 and not to position Rp or the highest impurity concentration region in at least a portion of the second active layer A2. However, the aspect of the present specification is not limited thereto, and may be applied as long as the Rp or the highest concentration region is positioned in the first active layer A1 and Rp or the highest concentration region is not positioned in at least a part of the second active layer A2.

In addition, dopant concentrations in the first ion implantation process and the second ion implantation process may be set to be the same or different from each other. As described in FIGS. 2B, 3B, and 3C, Rp of the first ion implantation process and the second ion implantation process may be formed at different positions, and the concentrations of the first and second active layers A1 and A2 according to the dopant concentration may be appropriately adjusted according to an electrical value required by the first and second thin film transistors TR1 and TR2.

For example, to increase the electrical characteristic margin and process margin by minimizing or reducing the difference in threshold voltages between the first and second thin film transistors TR1 and TR2, in general, a relatively high concentration of ion implantation process may be performed on the first thin film transistor TR1 having a relatively high threshold voltage due to a long gate channel length for the purpose of lowering the threshold voltage, and a relatively low concentration ion implantation process may be performed on the second thin film transistor TR2 having a relatively low threshold voltage due to a short gate channel length for the purpose of raising the threshold voltage less.

Referring to FIG. 7D, a thin film transistor substrate 1 including a first thin film transistor TR1 and a second thin film transistor TR2 may be prepared by removing a second photoresist pattern PR2 and forming a source electrode and a drain electrode of the first thin film transistor TR1 and the second thin film transistor TR2.

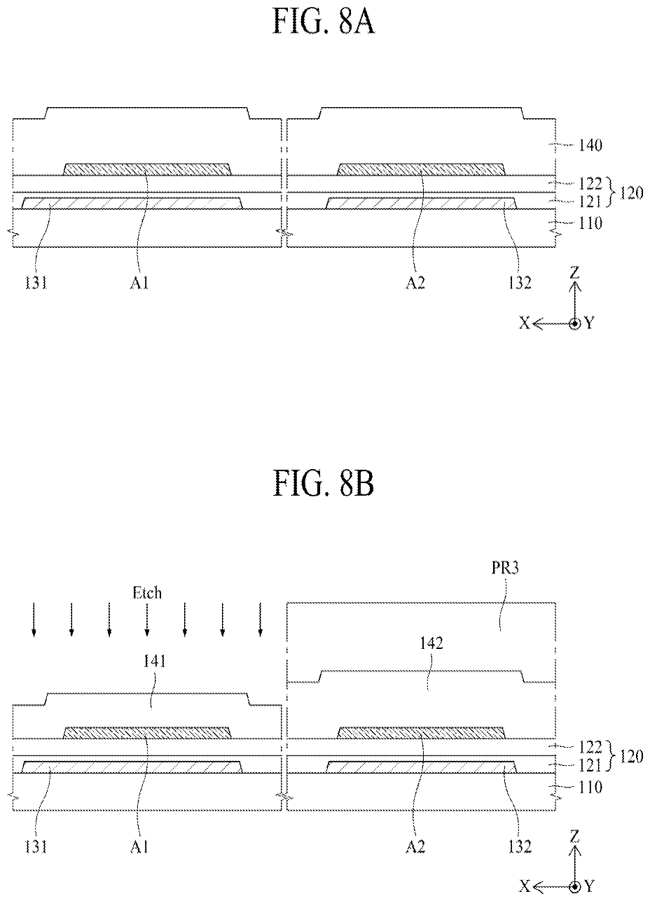

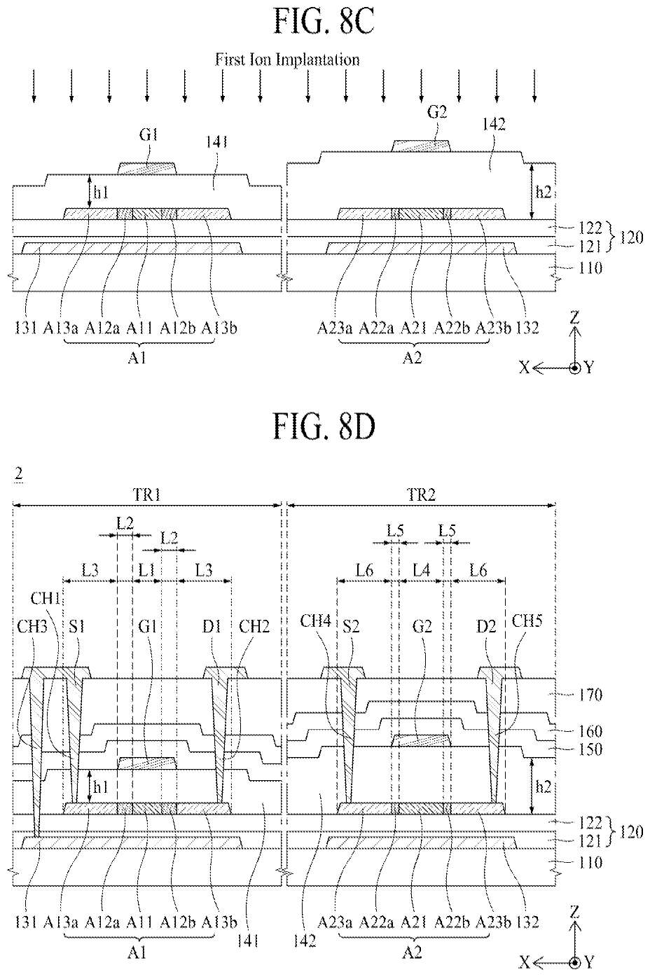

FIGS. 8A to 8D illustrate a method of manufacturing a thin film transistor substrate according to another exemplary aspect of the present specification.

A method of manufacturing the thin film transistor substrate according to another exemplary aspect of the present specification of FIGS. 8A to 8D describes a method of manufacturing the thin film transistor substrate according to another exemplary aspect of the present specification of FIG. 6. In addition, since the manufacturing method of the thin film transistor substrate according to another exemplary aspect of FIGS. 8A to 8D differs only in some steps from the manufacturing method of the thin film transistor substrate according to the aspect of FIGS. 7A to 7D, the same reference numerals as those of the thin film transistor substrate 1 of FIG. 6 are used, and the same or similar description will be omitted or briefly given.

Referring to FIG. 8A, a first light blocking layer 131 and a second light blocking layer 132 are patterned on a base substrate 110 in corresponding regions of the first thin film transistor TR1 and the second thin film transistor TR2, and a buffer layer 120 including first and second buffer layers 121 and 122 is formed on the base substrate 110. Next, a first active layer A1 and a second active layer A2 are patterned on the buffer layer 120 in corresponding regions of the first thin film transistor TR1 and the second thin film transistor TR2, and a gate insulating layer 140 is formed on the buffer layer 120 and the active layers A1 and A2.

Referring to FIG. 8B, the third photoresist pattern PR3 is formed to overlap with the corresponding region of the second thin film transistor TR2, and an etching process is performed. The etching process may be performed to remove at least a portion of the gate insulating layer 140 of the first thin film transistor TR1. After the etching process being performed, the gate insulating layers of the first thin film transistor TR1 and the second thin film transistor TR2 may have different thicknesses or heights. The first thin film transistor TR1 may include a first gate insulating layer 141 having a first height h1, the second thin film transistor TR2 may include a second gate insulating layer 142 having a second height h2, and the first height h1 of the first gate insulating layer 141 may be lower than the second height h2 of the second gate insulating layer 142.

For example, the height difference between the first gate insulating layer 141 and the second gate insulating layer 142 may be set to 50 nm to 150 nm, without being limited thereto. For example, if the first gate insulating layer 141 has a thickness of 150 nm, the second gate insulating layer 142 may be set to have a thickness of 250 nm.

Referring to FIG. 8C, the third photoresist pattern PR3 is removed, the first gate electrode G1 is formed to overlap with at least partially with the first active layer A1, and the second gate electrode G2 is formed to overlap with at least partially with the second active layer A2. Next, a first ion implantation process is performed. The first ion implantation process may be performed on the first gate electrode G1 of the first thin film transistor TR1, the first gate insulating layer 141, the second gate electrode G2 of the second thin film transistor TR2, and the second gate insulating layer 142. In addition, the method may optionally include a heat treatment process for ion or impurity diffusion after performing the first ion implantation process.

In addition, in FIG. 8C, the ion injection process may be simultaneously performed on the first active layer A1 and the second active layer A2 in a single process, but a first height h1 of the first gate insulating layer 141 may have a value smaller than a second height h2 of the second gate insulating layer 142. Therefore, a distance from the upper surface of the second gate insulating layer 142 to the second active layer A2 in which the first ion implantation process is performed may be longer than a distance from the upper surface of the first gate insulating layer 141 to the active layer A1. In this case, an acceleration energy of the first ion implantation process may be adjusted so that the Rp or highest impurity concentration region may overlap with at least a portion of the first active layer A1, not overlap with the second active layer A2, and overlap with at least a portion of the second gate insulating layer 142 overlapping with the second active layer A2.

In this case, in the second thin film transistor TR2, the thickness of the second gate insulating layer 142 increases, and the dopant concentration formed in the second active layer A2 decreases, thereby reducing the threshold voltage reduction due to the ion implantation process, and in the first thin film transistor TR1, the thickness of the first gate insulating layer 141 decreases, and the dopant concentration formed in the first active layer A1 increases, thereby increasing relatively the threshold voltage reduction due to the ion implantation process. Accordingly, the threshold voltage deviation between the first thin film transistor TR1 and the second thin film transistor TR2 is reduced, so that a margin of electrical characteristics may be secured. In addition, when the margin of electrical characteristics of the thin film transistor substrate according to this specification increases, there is an advantage in that the process margin forming the thin film transistor substrate is also secured.

Referring to FIG. 8D, the thin film substrate 2 including the first thin film transistor TR1 and the second thin film transistor TR2 may be prepared by forming the first to third interlayer insulating layers 150, 160 and 170, and forming a source electrode and a drain electrode of the first thin film transistor TR1 and the second thin film transistor TR2.

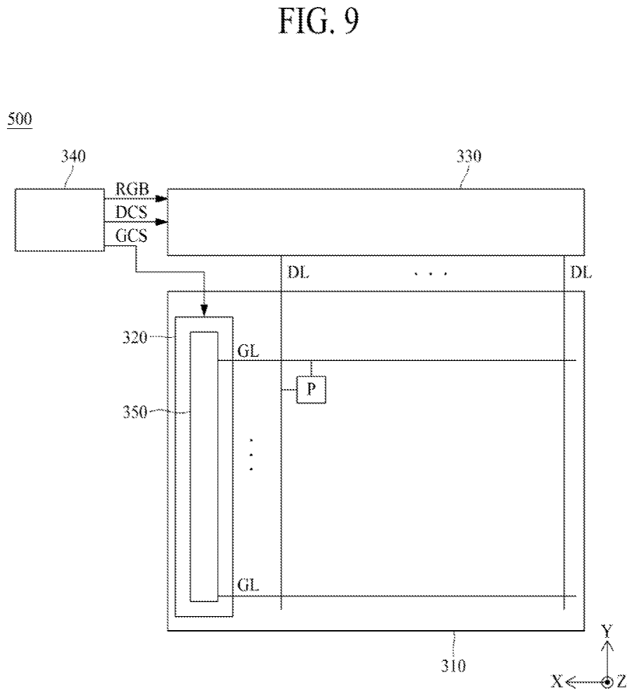

FIG. 9 is a schematic diagram of a display apparatus according to an exemplary aspect of the present specification.

The display apparatus 500 according to an exemplary aspect of the present specification includes a display panel 310, a gate driver 320, a data driver 330, and a controller 340, etc., as shown in FIG. 9.

Gate lines GLs and data lines DLs are disposed on the display panel 310, and pixels P are disposed in an intersection area between the gate lines GLs and data lines DLs. An image is displayed by driving the pixel P.

The controller 340 controls the gate driver 320 and the data driver 330.

The controller 340 outputs a gate control signal GCS for controlling the gate driver 320 and a data control signal DCS for controlling the data driver 330 using a signal supplied, for example, from an external system (not shown). In addition, the controller 340 samples input image data input, for example, from the external system and rearranges it, and supplies the rearranged digital image data RGB to the data driver 330.

The gate control signal GCS may include a gate start pulse, a plurality of gate shift clocks, a gate output enable signal, and the like. In addition, the gate control signal GCS may include control signals for controlling the shift register.

The data control signal DCS may include a source start pulse, a source shift clock signal, a source output enable signal, and the like.

The data driver 330 supplies a data voltage to the data lines DL of the display panel 310. Specifically, the data driver 330 converts the image data RGB input from the controller 340 into an analog data voltage and supplies the data voltage to the data lines DL.

The gate driver 320 may include a shift register 350.

The shift register 350 supplies gate pulses to the gate lines GLs in a predetermined order during one frame using a start signal and a gate shift clock, for example, transmitted from the controller 340. Here, one frame refers to a period during which one image is output through the display panel 310. The gate pulse has a turn-on voltage capable of turning on a switching element (thin film transistor) disposed in the pixel P.

In addition, the shift register 350 supplies a gate-off signal to the gate line GL to turn off the switching element for the rest of the frame when the gate pulse is not supplied. Hereinafter, the gate pulse and the gate-off signal are collectively referred to as a scan signal SS.

According to an exemplary aspect of the present specification, the gate driver 320 may be mounted on the base substrate 110. As described above, a structure in which the gate driver 320 is directly mounted on the base substrate 110 is referred to as a gate in panel GIP structure. But aspects are not limited thereto. As an example, the gate driver 320 may be connected to a bonding pad of the display panel 310 by a tape automated bonding TAB method or a chip-on-glass COG method. Alternatively, the gate driver 320 may be implemented by a chip-on-film COF method in which an element is mounted on a film connected to the display panel 310.

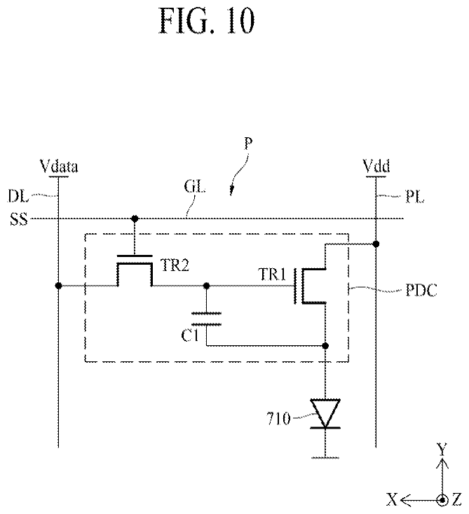

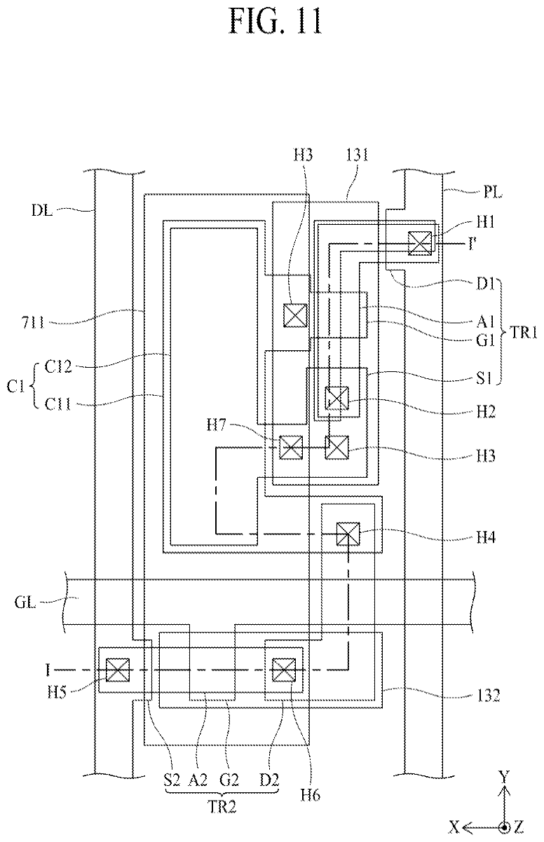

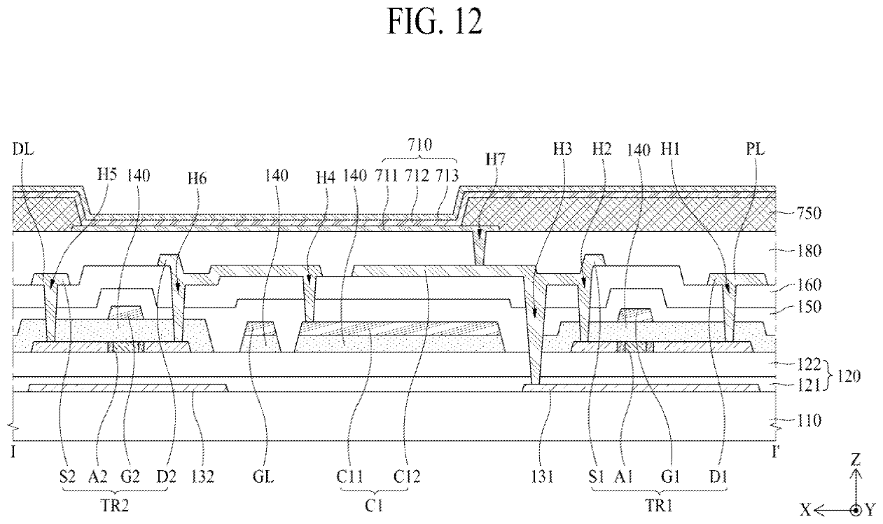

FIG. 10 is a circuit diagram of any one pixel P of FIG. 9, FIG. 11 is a plan view of the pixel P of FIG. 10, and FIG. 12 is a cross-sectional view taken along I-I′ of FIG. 11.

The circuit diagram of FIG. 10 is an equivalent circuit diagram of a pixel P of a display apparatus 500 including an organic light emitting diode OLED as a display element 710, without being limited thereto. As an example, the pixel P of a display apparatus 500 may include a light emitting diode LED etc. as a display element 710. The pixel P includes a display element 710 and a pixel driving unit PDC driving the display element 710.

According to another exemplary aspect of the present specification, the display apparatus 500 includes a pixel driving unit PDC and a display element 710. The pixel driving unit PDC includes a first thin film transistor TR1 and a second thin film transistor TR2. The first thin film transistor TR1 may include the same or similar structure as the first thin film transistor TR1 of the thin film transistor substrate 1 according to the exemplary aspect and/or the thin film transistor TR1 of the thin film transistor substrate 2 according to another exemplary aspect of the present specification. The second thin film transistor TR2 may include the same or similar structure as the second thin film transistor TR2 of the thin film transistor substrate 1 according to the exemplary aspect and the second thin film transistor TR2 of the thin film transistor substrate 2 according to another exemplary aspect of the present specification.

According to another exemplary aspect of the present specification, the first thin film transistor TR1 is a driving transistor, and the second thin film transistor TR2 is a switching transistor, without being limited thereto.

The second thin film transistor TR2 is connected to the gate line GL and the data line DL, and is turned on or off by the scan signal SS supplied through the gate line GL.

The data line DL provides the data voltage Vdata to the pixel driver PDC, and the second thin film transistor TR2 controls the application of the data voltage Vdata.

The driving power line PL provides the driving voltage Vdd to the display element 710, and the first thin film transistor TR1 controls the driving voltage Vdd. The driving voltage Vdd is a pixel driving voltage for driving the organic light emitting diode OLED which is the display element 710.

When the second thin film transistor TR2 is turned on by the scan signal SS applied through the gate line GL from the gate driver 320, the data voltage Vdata supplied through the data line DL is supplied to the first gate electrode G1 of the first thin film transistor TR1 connected to the display element 710. The data voltage Vdata is charged in the storage capacitor C1 formed between the first gate electrode G1 and the first source electrode S1 of the first thin film transistor TR1.

According to the data voltage Vdata, the amount of current supplied to the organic light emitting diode OLED, which is the display element 710 through the first thin film transistor TR1, may be controlled, and accordingly, the gray scale of light output from the display element 710 may be controlled.

Referring to FIGS. 11 and 12, the first thin film transistor TR1 and the second thin film transistor TR2 are disposed on the base substrate 110.

The base substrate 110 may be a glass substrate, a thin glass substrate that may be bent or folded, a plastic substrate, or a silicon wafer substrate, etc. As the plastic, transparent plastic having flexible properties, for example, polyimide, may be used. When polyimide is used as the base substrate 110, considering that a high-temperature deposition process is performed on the base substrate 110, a heat-resistant polyimide capable of enduring high temperatures may be used. But aspects are not limited thereto. As an example, the base substrate 110 may also be a rigid substrate that may not be bent or rolled.

Light blocking layers 131 and 132 may be optionally disposed on the base substrate 110.

The light blocking layers 131 and 132 may protect the active layers A1 and A2 and the first and second thin film transistors TR1 and TR2 by blocking light, for example, light incident from the outside. The light blocking layers 131 and 132 may be made of a material having light blocking characteristics or light reflection characteristics. As an example, the light blocking layers 131 and 132 may include a lower light blocking layer and an upper light blocking layer. The light blocking layers 131 and 132 may not be disposed on the entire surface of the base substrate 110 but may be disposed only on at least a portion overlapping with the thin film transistors TR1 and/or TR2 or the first active layer A1 and/or the second active layer A2. For example, the first light blocking layer 131 may be formed to overlap with the first thin film transistor TR1 or the first active layer A1 of the first thin film transistor TR1, and the second light blocking layer 132 may be formed to overlap with the second thin film transistor TR2 or the second active layer A2 of the second thin film transistor TR2.

A buffer layer 120 may be disposed on the light blocking layers 131 and 132 and the base substrate 110.

The buffer layer 120 may be formed of a multilayer film where one or more inorganic films of a silicon oxide layer SiOx, a silicon nitride layer SiN, and a silicon oxynitride layer SiON are laminated, without being limited thereto. For example, the buffer layer 120 may include a first buffer layer 121 on the base substrate 110 and a second buffer layer 122 on the first buffer layer 121. Other components of the thin film transistors TR1 and TR2 including gate electrodes G1 and G2 of the first and second thin film transistors TR1 and TR2 to be described later may be disposed on the buffer layer 120.

A first active layer A1 of the first thin film transistor TR1 and A second active layer A2 of the second thin film transistor TR2 are disposed on the buffer layer 120.

The first active layer A1 and the second active layer A2 of the first thin film transistor TR1 and the second thin film transistor TR2 may be disposed to overlap with the gate electrodes G1 and G2, the source electrodes S1 and S2, and the drain electrodes D1 and D2 of the first thin film transistor TR1 and the second thin film transistor TR2, respectively.

The first active layer A1 of the first thin film transistor TR1 includes a first channel part A11, first conductive parts A13a, A13b, and first conductive part penetration regions A12a, A12b, and the second active layer A2 of the second thin film transistor TR2 includes a second channel part A21, second conductive parts A23a and A23b, and second conductive part penetration regions A22a and A22b. Since the first channel part A11, the first conductive part A13a and A13b, the first conductive part penetration regions A12a and A12b, the second channel part A21, the second conductive part A23a and A23b, and the second conductive part penetration regions A22a and A22b are the same or similar as those described in FIG. 1, repeated descriptions will be omitted or briefly given.

A gate insulating layer 140 is disposed on the first active layer A1 of the first thin film transistor TR1, the second active layer A2 of the second thin film transistor TR2, and the buffer layer 120, disposed between the first active layer A1 and the first gate electrode G1 of the first thin film transistor TR1, and between the second active layer A2 and the second gate electrode G2 of the second thin film transistor TR2, and protects the first active layer A1 of the first thin film transistor TR1 and the second active layer A2 of the second thin film transistor TR2. The gate insulating layer 140 may include a silicon nitride layer SiNx or a silicon oxide layer SiOx, but is not limited thereto. The gate insulating layer 140 may have a single layer structure or a multilayer structure.

A first capacitor electrode C11 of a storage capacitor C1 is disposed on the gate insulating layer 140. The first capacitor electrode C11 may be connected to the first gate electrode G1 of the first thin film transistor TR1. The first capacitor electrode C11 may be integrally formed with the first gate electrode G1 of the first thin film transistor TR1.

The first gate electrode G1 of the first thin film transistor TR1 and the second gate electrode G2 of the second thin film transistor TR2 are disposed on the gate insulating layer 140. The first gate electrode G1 of the first thin film transistor TR1 and the second gate electrode G2 of the second thin film transistor TR2 overlap with the channel parts of the active layers A1 and A2, respectively.

The first gate electrode G1 of the first thin film transistor TR1 and the second gate electrode G2 of the second thin film transistor TR2 may include at least one of an aluminum-based metal such as aluminum Al or an aluminum alloy, a silver-based metal such as silver Ag or a silver alloy, a copper-based metal such as copper Cu or a copper alloy, a molybdenum-based metal such as molybdenum Mo or a molybdenum alloy, chromium Cr, tantalum Ta, neodymium Nd, titanium Ti, and etc. The first gate electrode G1 of the first thin film transistor TR1 and the second gate electrode G2 of the second thin film transistor TR2 may have a single layer structure or a multilayer structure including at least two conductive layers having the same or different physical properties.

A first interlayer insulating layer 150 may be disposed on the first gate electrode G1 and the gate insulating layer 140, and a second interlayer insulating layer 160 may be disposed on the first interlayer insulating layer 150.

The first interlayer insulating layer 150 and the second interlayer insulating layer 160 may include, for example, a silicon oxide layer SiOx or a silicon nitride layer SiNx, and may function to protect a thin film transistor. To contact the first active layer A1 of the first thin film transistor TR1 and the second active layer A2 of the second thin film transistor TR2, respectively, with the source electrodes and the drain electrodes, a portion of the first interlayer insulating layer 150 and the second interlayer insulation layer 160 corresponding to contact holes may be removed. The first source electrode S1 and the first drain electrode D1 of the first thin film transistor TR1, and the second source electrode S2 and the second drain electrode D2 of the second thin film transistor TR2 are disposed on the interlayer insulating layer 160. The data line DL, the driving power line PL, and a second capacitor electrode C12 of the storage capacitor C1 may be disposed on the interlayer insulating layer 160.

A portion of the driving power line PL may extend to become the first drain electrode D1 of the first thin film transistor TR1. The first drain electrode D1 of the first thin film transistor TR1 is connected to the first active layer A1 through a first contact hole H1.

The first source electrode S1 of the first thin film transistor TR1 may be connected to the first active layer A1 through a second contact hole H2 and may optionally be connected to the first light blocking layer 131 through a third contact hole H3.

The first source electrode S1 of the first thin film transistor TR1 and the second capacitor electrode C12 may be connected to each other. As an example, the first source electrode S1 of the first thin film transistor TR1 and the second capacitor electrode C12 may be integrally formed.

A portion of the data line DL may extend to become the second source electrode S2 of the second thin film transistor TR2. The second source electrode S2 of the second thin film transistor TR2 may be connected to the second active layer A2 through a fifth contact hole H5.

The second drain electrode D2 of the second thin film transistor TR2 may be connected to the second active layer A2 through a sixth contact hole H6, and may be connected to the first capacitor electrode C11 through another fourth contact hole H4.

A planarization layer 180 is disposed on the first source electrode S1, the first drain electrode D1 of the first thin film transistor TR1, the second source electrode S2, the second drain electrode D2 of the second thin film transistor TR2, the data line DL, the driving power line PL, and the second capacitor electrode C12.

The planarization layer 180 is formed of an insulating layer, and planarizes upper portions of the first thin film transistor TR1 and the second thin film transistor TR2, and protects the first thin film transistor TR1 and the second thin film transistor TR2.

A first pixel electrode 711 of the display element 710 is disposed on the planarization layer 180. The first pixel electrode 711 contacts the second capacitor electrode C12 through a seventh contact hole H7 formed in the planarization layer 180. As a result, the first pixel electrode 711 may be connected to the first source electrode S1 of the first thin film transistor TR1. The seventh contact hole H7 connected to the first pixel electrode 711 and formed in the planarization layer 180 may be formed in the non-opening area of the display element 710 to overlap with a bank layer 750.

The bank layer 750 is disposed at an edge of the first pixel electrode 711. The bank layer 750 defines a light emitting area of the display element 710.

An organic light emitting layer 712 is disposed on the first pixel electrode 711, and a second pixel electrode 713 is disposed on the organic light emitting layer 712. Accordingly, the display element 710 is configured. The display element 710 shown in FIGS. 11 and 12 is an organic light emitting diode OLED. Accordingly, the display apparatus 500 according to another exemplary aspect of the present specification may be an organic light emitting display apparatus. But aspects are not limited thereto. For example, the display element 710 may be a light emitting diode LED. Accordingly, the display apparatus 500 according to another exemplary aspect of the present specification may be an LED display apparatus.

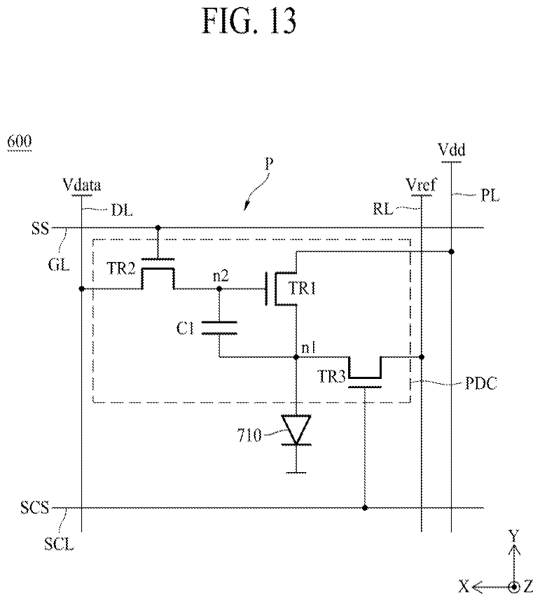

FIG. 13 is a circuit diagram of any one pixel of a display apparatus according to another exemplary aspect of the present specification.

The pixel P of the display apparatus 600 shown in FIG. 13 includes an organic light emitting diode OLED that is a display element 710 and a pixel driving unit PDC that drives the display element 710, without being limited thereto. The display element 710 is connected to the pixel driving unit PDC, and the pixel driving unit PDC includes three thin film transistors and one capacitor.

Signal lines DL, GL, PL, RL, and SCL for supplying a signal to the pixel driving unit PDC are disposed in the pixel P.

A data voltage Vdata is supplied to the data line DL, a scan signal SS is supplied to the gate line GL, a driving voltage Vdd for driving pixels is supplied to the driving power line PL, a reference voltage Vref is supplied to the reference line RL, and a sensing control signal SCS is supplied to the sensing control line SCL.

The pixel driving unit PDC includes, for example, a second thin film transistor TR2 (or switching transistor) connected to the gate lines GL and the data lines DL, a first thin film transistor TR1 (or driving transistor) which controls the magnitude of the current output to the display element 710 according to the data voltage Vdata transmitted through the second thin film transistor TR2 and a third thin film transistor (or reference transistor) for detecting a characteristic of the first thin film transistor TR1.

The storage capacitor C1 is positioned between the gate electrode of the first thin film transistor TR1 and the display element 710.

The second thin film transistor TR2 is turned on by a scan signal SS supplied to the gate line GL to transmit the data voltage Vdata supplied to the data line DL to the gate electrode of the first thin film transistor TR1.

The third thin film transistor TR3 is connected to the first node n1 between the first thin film transistor TR1 and the display element 710 and the reference line RL, is turned on or off by the sensing control signal SCS, and detects the characteristics of the first thin film transistor TR1, which is a driving transistor, during a sensing period.

The second node n2 connected to the gate electrode of the first thin film transistor TR1 is connected to the second thin film transistor TR2. A storage capacitor C1 is formed between the second node n2 and the first node n1.

When the second thin film transistor TR2 is turned on, the data voltage Vdata supplied through the data line DL is supplied to the gate electrode of the first thin film transistor TR1. The data voltage Vdata is charged in the first capacitor C1 formed between the gate electrode and the source electrode of the first thin film transistor TR1.

When the first thin film transistor TR1 is turned on, the current is supplied to the display element 710 through the first thin film transistor TR1 by the driving voltage Vdd driving the pixel, and light is output from the display element 710.

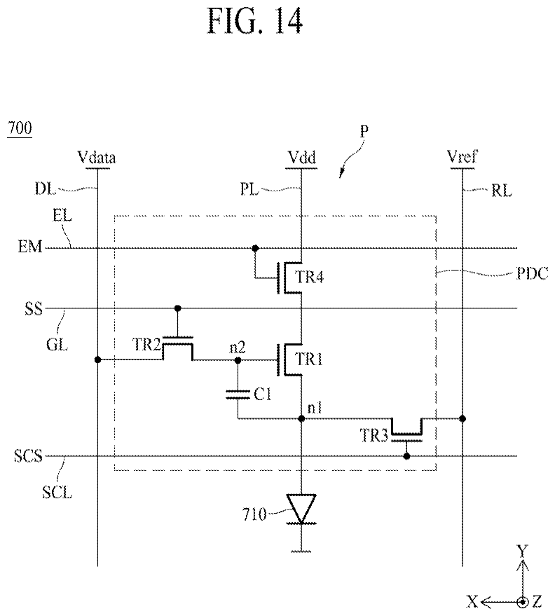

FIG. 14 is a circuit diagram of any one pixel of a display apparatus according to another exemplary aspect of the present specification.

The pixel P of the display apparatus 700 shown in FIG. 14 includes an organic light emitting diode OLED that is a display apparatus 710 and a pixel driving unit PDC that drives the display apparatus 710, without being limited thereto. The display element 710 is connected to the pixel driving unit PDC, and the pixel driving unit PDC includes four thin film transistors and one capacitor.

The pixel driving unit PDC includes thin film transistors TR1, TR2, TR3, and TR4.

Signal lines DL, EL, GL, PL, SCL, and RL for supplying a driving signal to the pixel driving unit PDC are disposed in the pixel P.

The pixel P of FIG. 14 further includes an emission control line EL compared with the pixel P of FIG. 13. An emission control signal EM is supplied to the emission control line EL.

In addition, the pixel driving unit PDC of FIG. 14 further includes a fourth thin film transistor TR4, which is a light emission control transistor for controlling the light emission point of the first thin film transistor TR1, compared to the pixel driving unit PDC of FIG. 13.

The storage capacitor C1 is positioned between the gate electrode of the first thin film transistor TR1 and the display element 710.

The second thin film transistor TR2 is turned on by a scan signal SS supplied to the gate line GL to transmit the data voltage Vdata supplied to the data line DL to the gate electrode of the first thin film transistor TR1.

The third thin film transistor TR3 is connected to the reference line RL, is turned on or off by the sensing control signal SCS, and detects the characteristics of the first thin film transistor TR1, which is a driving transistor, during the sensing period

The fourth thin film transistor TR4 transmits the driving voltage Vdd to the first thin film transistor TR1 or blocks the driving voltage Vdd according to the emission control signal EM. When the fourth thin film transistor TR4 is turned on, a current is supplied to the first thin film transistor TR1, and light is output from the display element 710.

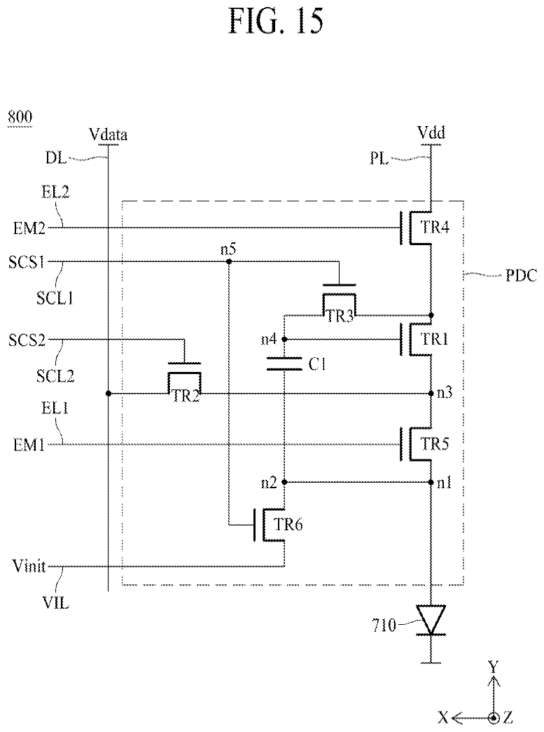

FIG. 15 is a circuit diagram of any one pixel of a display apparatus according to another exemplary aspect of the present specification.

The pixel P of the display apparatus 700 shown in FIG. 15 includes an organic light emitting diode OLED that is a display apparatus 710 and a pixel driving unit PDC that drives the display element 710, without being limited thereto. The display element 710 is connected to the pixel driving unit PDC, and the pixel driving unit PDC includes six thin film transistors and one capacitor.

The pixel driving unit PDC includes thin film transistors TR1, TR2, TR3, TR4, TR5, and TR6.

Signal lines DL, EL1, EL2, PL, SCL1, SCL2, and VIL that supply a driving signal to the pixel driving unit PDC are disposed in the pixel P.

Compared with the pixel P of FIG. 14, the pixel P of FIG. 15 further includes first and second emission control lines EL1, EL2, initial voltage lines VIL, and first and second sensing control lines SCL1 and SCL2, and the first and second emission control signals EM1 and EM2 are supplied to the first and second emission control lines EL1 and EL2, an initialization voltage Vinit is supplied to the initial voltage lines VIL, and first and second sensing control signals SCS1 and SCS2 is supplied through the first and second sensing control lines SCL1 and SCL2.

The second thin film transistor TR2 includes a gate electrode connected to the second sensing control line SCL2, a drain electrode connected to the data line DL, and a source electrode connected to the source electrode of the first thin film transistor TR1. The source electrode of the second thin film transistor TR2 and the source electrode of the first thin film transistor TR1 may be connected, for example, connected at a third node n3.

The gate electrode of the first thin film transistor TR1 (or driving transistor) stores the high potential voltage Vdd when the third thin film transistor TR3 and the fourth thin film transistor TR4 are turned on. When the data voltage Vdata is supplied while the third thin film transistor TR3 is turned on, the data voltage Vdata is supplied to the gate electrode of the first thin film transistor TR1 by a diode-connection method. The first thin film transistor TR1 supplies a driving current to the organic light emitting element 710 by the first and second emission control signals EM1 and EM2 to control the luminance of the organic light emitting element 710 according to the amount of current.

The third thin film transistor TR3 includes a gate electrode connected to the first scan signal line SCL1, a drain electrode connected to the source electrode of the fourth thin film transistor TR4, and a source electrode connected to the gate electrode of the first thin film transistor TR1. The source electrode of the third thin film transistor TR3 and the gate electrode of the first thin film transistor TR1 (driving transistor) may be connected, for example, connected at the fourth node.

The fourth thin film transistor TR4 includes a gate electrode connected to the second light emission control signal line EL2, a drain electrode connected to the high potential voltage line PL, and a source electrode connected to the drain electrode of the first thin film transistor TR1. Accordingly, the fourth thin film transistor TR4 is turned on by the second light emission control signal line EL2 and supplies the high potential voltage Vdd to the drain electrode of the first thin film transistor TR1.

The fifth thin film transistor TR5 includes a gate electrode connected to the first light emitting control line EL1, a drain electrode connected to the source electrode of the first thin film transistor TR1, and a source electrode electrically connected to the display element 710. The fifth thin film transistor TR5 may be turned on by the first emission control signal EM1.

Accordingly, when the fifth thin film transistor TR5 is turned on by the first emission control signal EM1, the voltage of the third node n3 is supplied to the first node n1. When the fifth thin film transistor TR5, the first thin film transistor TR1, and the fourth thin film transistor TR4 are turned on, a high potential voltage Vdd is supplied to the first thin film transistor TR1 and a driving current is supplied to the display element 710 so that the display element 710 may emit light.

The sixth thin film transistor TR6 includes a gate electrode connected to the first scan signal line SCL1, a drain electrode connected to the initialization voltage Vinit line, and a source electrode connected to the first node n1, which is an anode of the display element 710. Accordingly, the sixth thin film transistor TR6 may be turned on by the first scan signal SCS1, and the first scan signal SCS1 may be branched from the fifth node n5. Accordingly, when the sixth thin film transistor TR6 is turned on by the first scan signal SCS1, the initialization voltage Vini is supplied to the second node n2 and the first node n1, and the data voltage Vdata supplied in the display element 710 is initialized.

The capacitor C1 may be a storage capacitor C1 that stores a voltage applied to the gate electrode of the first thin film transistor TR1. Here, the capacitor C1 is disposed between the fourth node n4 connected to the gate electrode of the first thin film transistor TR1 and the second node n2 electrically connected to the anode of the display element 710. That is, the capacitor C1 is electrically connected to the second node n2 and the fourth node n4 to store the difference between the voltage of the gate electrode of the first thin film transistor TR1 and the voltage supplied to the anode of the display element 710.

The pixel driving unit PDC according to another exemplary aspect of the present specification may be formed in various structures other than the above-described structure. For example, more or less transistors and/or more or less capacitors could be included in the pixel driving unit.

Accordingly, the present disclosure may have the following advantages.

According to an exemplary aspect of the present disclosure, the thin film transistor substrate may have different conductive part penetration region lengths, particularly with respect to a plurality of transistors provided on the same plane.

According to an exemplary aspect of the present disclosure, the thin film transistor substrate has different electrical characteristics or electrical behavior of short channel length for a plurality of transistors, particularly for those provided on the same plane, such as threshold voltage, hot carrier stress (HCS), drain induced barrier lowering (DIBL), and threshold voltage roll-off.

According to an exemplary aspect of the present disclosure, the thin film transistor substrate has different electrical characteristics or electrical behavior, thus reducing the short channel effect of the thin film transistor used as a switching transistor with a short channel length, and securing the threshold voltage of the thin film transistor used as a driving transistor. therefore, the margin of electrical characteristics may be secured, and furthermore, the process margin of the thin film transistor substrate may be secured according to the margin of electrical characteristics.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate comprising:
a first thin film transistor disposed on a base substrate; and
a second thin film transistor spaced apart from the first thin film transistor,
wherein the first thin film transistor comprises a first active layer and a first gate electrode that overlaps with at least a portion of the first active layer,
wherein the second thin film transistor comprises a second active layer and a second gate electrode that overlaps with at least a portion of the second active layer,
wherein the first active layer includes a first channel part overlapping with the first gate electrode, and a first conductive part penetration region disposed at an end of the first channel part,
wherein the second active layer includes a second channel part overlapping with the second gate electrode, and a second conductive part penetration region disposed at an end of the second channel part, and
wherein a length of the first conductive part penetration region is longer than a length of the second conductive part penetration region.

2. The thin film transistor substrate according to the claim 1, wherein the first conductive part penetration region overlaps with the first gate electrode, and the second conductive part penetration region overlaps with the second gate electrode.

3. The thin film transistor substrate according to the claim 1, wherein an impurity concentration of the first conductive part penetration region is higher than an impurity concentration of the second conductive part penetration region.

4. The thin film transistor substrate according to the claim 1, wherein the first active layer further includes a first conductive part formed at one side of the first conductive part penetration region opposite to the first channel part, and
wherein the second active layer further includes a second conductive part formed at one side of the second conductive part penetration region opposite to the second channel part.

5. The thin film transistor substrate according to the claim 4, wherein an impurity concentration of the first conductive part is higher than an impurity concentration of the second conductive part.

6. The thin film transistor substrate according to the claim 4, wherein the first conductive part does not overlap with the first gate electrode, and the second conductive part does not overlap with the second gate electrode.

7. The thin film transistor substrate according to the claim 4, wherein an impurity concentration of the first conductive part penetration region increases in a direction from the end of the first channel part toward the first conductive part, and
an impurity concentration of the second conductive part penetration region increases in a direction from the end of the second channel part toward the second conductive part.

8. The thin film transistor substrate according to the claim 1, further comprising a gate insulating layer disposed between the first active layer and the first gate electrode and between the second active layer and the second gate electrode.

9. The thin film transistor substrate according to the claim 8, wherein the gate insulating layer includes a first gate insulating layer disposed between the first active layer and the first gate electrode, and a second gate insulating layer disposed between the second active layer and the second gate electrode.

10. The thin film transistor substrate according to the claim 9, wherein a thickness of the first gate insulating layer is thinner than a thickness of the second gate insulating layer.

11. The thin film transistor substrate according to the claim 1, further comprising a first interlayer insulating layer disposed on the first thin film transistor and the second thin film transistor.

12. The thin film transistor substrate according to the claim 8, wherein a portion of the gate insulating layer overlapping with the first thin film transistor is doped with impurities doped in the first active layer.

13. The thin film transistor substrate according to the claim 11, wherein a portion of the first interlayer insulating layer overlapping with the first thin film transistor is not doped with impurities doped in the first active layer.

14. The thin film transistor substrate according to the claim 11, wherein a portion of the first interlayer insulating layer overlapping with the second thin film transistor is doped with impurities doped in the second active layer.

15. The thin film transistor substrate according to the claim 4, wherein a highest value of a distribution of an impurity concentration along a vertical direction of a region overlapping with the first conductive part overlaps with at least partially with the first active layer, and
a highest value of a distribution of an impurity concentration along a vertical direction of a region overlapping with the second conductive part does not overlap with the second active layer.

16. The thin film transistor substrate according to the claim 4, further comprising:
a gate insulating layer disposed between the first active layer and the first gate electrode and between the second active layer and the second gate electrode, and
a first interlayer insulating layer disposed on the first thin film transistor and the second thin film transistor,
wherein an impurity concentration is distributed from the gate insulating layer to the first active layer along a vertical direction of a region overlapping with the first conductive part, with the highest value overlapping with at least partially with the first active layer, and
an impurity concentration is distributed from the first interlayer insulating layer to the second active layer along a vertical direction of a region overlapping with the second conductive part, with the highest value overlapping with the gate insulating layer.

17. The thin film transistor substrate according to the claim 1, wherein the first active layer and the second active layer are formed on a same layer.

18. The thin film transistor substrate according to the claim 1, wherein the first thin film transistor is a driving transistor for driving a display element of a pixel driving unit of a display apparatus.

19. The thin film transistor substrate according to the claim 1, wherein the second thin film transistor constitutes a gate driver of a gate-in-panel circuit of a display apparatus.

20. The thin film transistor substrate according to the claim 1, wherein the second thin film transistor is a switching transistor of a pixel driving unit of a display apparatus.

21. A display apparatus comprising a plurality of pixels, each of which includes a display element and a pixel driving unit configured to drive the display element,
wherein the pixel driving unit comprises the thin film transistor substrate of claim 1.

22. The display apparatus according to the claim 21, wherein the pixel driving unit comprises:
a driving transistor configured to supply a current to the display element according to a data voltage, and
a switching transistor configured to supply the data voltage to a gate electrode of the driving transistor according to a scan signal, and
wherein the first thin film transistor constitutes the driving transistor.

23. The display apparatus according to the claim 22, wherein the second thin film transistor constitutes the switching transistor.

24. The display apparatus according to claim 21, further comprising a gate driver of a gate-in-panel circuit for supplying the scan signal,
wherein the second thin film transistor constitutes the gate driver.

25. A method of manufacturing a thin film transistor substrate comprising:
a step of forming a first active layer and a second active layer on a base substrate;
a step of forming a gate insulating layer on the first active layer and the second active layer;
a step of forming a first gate electrode to overlap with at least a portion of the first active layer;
a step of forming a second gate electrode to overlap with at least a portion of the second active layer;
a step of performing a first impurity implantation process on the first active layer, and
a step of performing a second impurity implantation process on the second active layer,
wherein the first active layer includes a first channel part overlapping with the first gate electrode, and a first conductive part penetration region formed at an end of the first channel part,
the second active layer includes a second channel part overlapping with the second gate electrode, and a second conductive part penetration region formed at an end of the second channel part, and
a length of the first conductive part penetration region is longer than a length of the second conductive part penetration region.

26. The method of manufacturing the thin film transistor substrate according to the claim 25, wherein the step of performing a first impurity implantation process includes forming a second photoresist pattern to overlap with the second active layer, and the step of performing a second impurity implantation process includes forming a second photoresist pattern to overlap with the first active layer.

27. The method of manufacturing the thin film transistor substrate according to the claim 26, further comprising, before the step of performing a second impurity implantation process on the second active layer, a step of forming a first interlayer insulating layer on the first gate electrode and the second gate electrode,
wherein the second photoresist pattern is formed on the first interlayer insulating layer.

28. The method of manufacturing the thin film transistor substrate according to the claim 27, wherein the first interlayer insulating layer includes hydrogenated silicon nitride (SiNx:H).

29. The method of manufacturing the thin film transistor substrate according to the claim 27, wherein an impurity implantation energy in the first impurity implantation process is higher than an impurity implantation energy in the second impurity implantation process.

30. The method of manufacturing the thin film transistor substrate according to the claim 27, wherein an impurity implantation concentration of the first impurity implantation process is equal to or smaller than an impurity implantation concentration of the second impurity implantation process.

31. The method of manufacturing the thin film transistor substrate according to the claim 25, further comprising a step of etching at least a portion of the gate insulating layer overlapping with the first active layer after forming the gate insulating layer,
wherein the gate insulating layer overlapping with the first active layer has a first thickness, the gate insulating layer overlapping with the second active layer has a second thickness, and the second thickness is thicker than the first thickness.

32. The method of manufacturing the thin film transistor substrate according to the claim 31, wherein the step of performing a first impurity implantation process and the step of performing a second impurity implantation process are carried out simultaneously.

33. The method of manufacturing the thin film transistor substrate according to the claim 25, wherein an impurity concentration of the first conductive part penetration region is higher than an impurity concentration of the second conductive part penetration region.

34. The method of manufacturing the thin film transistor substrate according to the claim 25, wherein the first active layer further includes a first conductive part formed at one side of the first conductive part penetration region opposite to the first channel part, and
the second active layer further includes a second conductive part formed at one side of the second conductive part penetration region opposite to the second channel part.

35. The method of manufacturing the thin film transistor substrate according to the claim 25, wherein a portion of the gate insulating layer overlapping with the first active layer is doped with impurities doped in the first active layer.

36. The method of manufacturing the thin film transistor substrate according to the claim 27, wherein a portion of the first interlayer insulating layer overlapping with the first active layer is not doped with impurities doped in the first active layer.

37. The method of manufacturing the thin film transistor substrate according to the claim 27, wherein a portion of the first interlayer insulating layer overlapping with the second active layer is doped with impurities doped in the second active layer.

38. The method of manufacturing the thin film transistor substrate according to the claim 31, wherein the gate insulating layer overlapping with the first active layer is doped with impurities doped in the first active layer, and the gate insulating layer overlapping with the second active layer is doped with impurities doped in the second active layer.

39. The method of manufacturing the thin film transistor substrate according to the claim 25, wherein a distance from a surface where the second impurity implantation process is performed to the second active layer is longer than a distance from a surface where the first impurity implantation process is performed to the first active layer.
